(19) United States
(12) Patent Application Publication
(10) Pub. No.: US 2026/0105262 A1
(43) Pub. Date: Apr. 16, 2026

(54) TEXT-CONDITIONED ANOMALY DETECTION FOR CHARGED-PARTICLE MICROSCOPY IMAGES

(71) Applicant: FEI Company, Hillsboro, OR (US)

(72) Inventors: Remco Geurts, Nuenen (NL); Pavel Potocek, Eindhoven (NL)

(21) Appl. No.: 18/913,013

(22) Filed: Oct. 11, 2024

(51) Int. Cl. G06F 40/40; G06F 40/30; G06T 7/00; G06T 7/73

(52) U.S. Cl. CPC G06F 40/40; G06F 40/30; G06T 7/0002; G06T 7/73; G06T 2207/10061

(57) ABSTRACT

Systems/techniques are provided for facilitating text-conditioned anomaly detection for charged-particle microscopy images. In various embodiments, a system can access an image captured by a charged-particle microscope, wherein the image depicts a specimen. In various aspects, the system can localize one or more outlying instantiations of a structure of interest of the specimen, based on feeding both the image and a text prompt to a large language model. In various instances, the text prompt can comprise one or more sentences or sentence fragments that semantically define or describe the one or more outlying instantiations. In various cases, the one or more sentences or sentence fragments can semantically define or describe the one or more outlying instantiations in terms of their sizes, shapes, distances, arrangements, or intensities with respect to other instantiations of the structure of interest.

### BACKGROUND

When given an image captured by a charged-particle microscope, localizing outlying structures of interest in that image can be difficult.

### SUMMARY

The following presents a summary to provide a basic understanding of one or more embodiments. This summary is not intended to identify key or critical elements, or delineate any scope of the particular embodiments or any scope of the claims. Its sole purpose is to present concepts in a simplified form as a prelude to the more detailed description that is presented later. In one or more embodiments described herein, devices, systems, computer-implemented methods, apparatus or computer program products that facilitate text-conditioned anomaly detection for charged-particle microscopy images are described.

According to one or more embodiments, a system is provided. The system can comprise a non-transitory computer-readable memory that can store computer-executable components. The system can further comprise a processor that can be operably coupled to the non-transitory computer-readable memory and that can execute the computer-executable components stored in the non-transitory computer-readable memory. In various embodiments, the computer-executable components can comprise an access component that can access an image captured by a charged-particle microscope, wherein the image depicts a specimen. In various aspects, the computer-executable components can comprise a localization component that can localize one or more outlying instantiations of a structure of interest of the specimen, based on feeding both the image and a text prompt to a large language model.

According to one or more embodiments, a computer-implemented method is provided. In various embodiments, the computer-implemented method can comprise accessing, by a device operatively coupled to a processor, an image captured by a charged-particle microscope, wherein the image depicts a specimen. In various aspects, the computer-implemented method can comprise localizing, by the device, one or more outlying instantiations of a structure of interest of the specimen, based on feeding both the image and a text prompt to a large language model.

According to one or more embodiments, a computer program product for facilitating text-conditioned anomaly detection for charged-particle microscopy images is provided. In various embodiments, the computer program product can comprise a non-transitory computer-readable memory having program instructions embodied therewith. In various aspects, the program instructions can be executable by a processor to cause the processor to access a charged-particle microscope and a text prompt, wherein the charged-particle microscope is loaded with a specimen, and wherein the text prompt describes an outlying characteristic that might be exhibited by various instantiations of a structure of interest of the specimen. In various instances, the program instructions can be executable to cause the processor to cause, in response to receipt of the text prompt, the charged-particle microscope to scan the specimen, thereby yielding a scanned image of the specimen. In various cases, the program instructions can be executable to cause the processor to generate one or more bounding boxes that circumscribe one or more instantiations of the structure of interest that exhibit the outlying characteristic, based on executing a large language model on both the scanned image and the text prompt.

### DESCRIPTION OF THE DRAWINGS

Various embodiments will be readily understood by the following detailed description in conjunction with the accompanying figures. To facilitate this description, like reference numerals designate like structural elements. Embodiments are illustrated by way of example, not by way of limitation, in the figures. The figures are not necessarily drawn to scale.

FIG. 1 illustrates an example, non-limiting block diagram of a scientific instrument module in accordance with various embodiments described herein.

FIG. 2 illustrates an example, non-limiting flow diagram of a computer-implemented method in accordance with various embodiments described herein.

FIG. 3 illustrates a block diagram of an example, non-limiting system that facilitates text-conditioned anomaly detection for charged-particle microscopy images in accordance with one or more embodiments described herein.

FIG. 4 illustrates a block diagram of an example, non-limiting system including a scanned image that facilitates text-conditioned anomaly detection for charged-particle microscopy images in accordance with one or more embodiments described herein.

FIG. 5 illustrates an example, non-limiting block diagram showing how a scanned image can be obtained in accordance with one or more embodiments described herein.

FIG. 6 illustrates a block diagram of an example, non-limiting system including a large language model and a set of outlier localizations that facilitates text-conditioned anomaly detection for charged-particle microscopy images in accordance with one or more embodiments described herein.

FIG. 7 illustrates an example, non-limiting block diagram showing how a set of outlier localizations can be obtained via a large language model in accordance with one or more embodiments described herein.

FIGS. 8-14 illustrate example, non-limiting dramatizations of localizations experimentally obtained by one or more embodiments described herein.

FIG. 15 illustrates an example, non-limiting block diagram showing how a large language model can be trained in accordance with one or more embodiments described herein.

FIG. 16 illustrates a block diagram of an example, non-limiting operating environment in which one or more embodiments described herein can be facilitated.

FIG. 17 illustrates an example networking environment operable to execute various implementations described herein.

FIG. 18 illustrates an example dual beam microscope that can be implemented in accordance with various embodiments described herein.

### DETAILED DESCRIPTION

The following detailed description is merely illustrative and is not intended to limit embodiments or application/uses of embodiments. Furthermore, there is no intention to be bound by any expressed or implied information presented in the preceding Background or Summary sections, or in the Detailed Description section.

One or more embodiments are now described with reference to the drawings, wherein like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

Various operations can be described as multiple discrete actions or operations in turn, in a manner that is most helpful in understanding the subject matter disclosed herein. However, the order of description should not be construed as to imply that these operations are necessarily order dependent. In particular, these operations can be performed in an order different from the order of presentation. Operations described can be performed in a different order from the described embodiments.

Various additional operations can be performed, or described operations can be omitted in additional embodiments.

Although some elements may be referred to in the singular (e.g., “a processing device”), any appropriate elements may be represented by multiple instances of that element, and vice versa. For example, a set of operations described as performed by a processing device may be implemented with different ones of the operations performed by different processing devices. As used herein, the phrase “based on” should be understood to mean “based at least in part on,” unless otherwise specified.

A charged-particle microscope (e.g., a scanning electron microscope (SEM), a transmission electron microscope (TEM), a dual beam microscope) can be any suitable computerized device that can capture or generate microscopic or nanoscopic images of specimens in a scientific, laboratory, research, or clinical operational environment. To facilitate the capture or generation of such images, charged-particle microscopes can leverage complex arrangements of actuatable parts (e.g., ion sources, electron sources, optical lenses or apertures, optical plates or deflectors, columns, coils, heaters, coolers, fluid valves, fluid pumps, circuit switches, specimen stages), sensors (e.g., ion detectors, electron detectors, voltmeters, thermistors, potentiometers, pressure gauges), or consumables (e.g., carrier fluids, calibrants, filters, reactive gases).

A specimen (e.g., an integrated circuit chip, a semiconductor wafer, a lamella, a biological or organic sample), whether synthetic (e.g., fabricated or manufactured via any suitable photolithographic techniques such as etching or deposition) or naturally-occurring, can have or otherwise contain any suitable structure of interest (e.g., fin, gate, drain, nanowire, organelle), where the structure of interest is repeated or duplicated multiple times on or in the specimen. In other words, the specimen can have or contain multiple instantiations, versions, or copies of the structure of interest. Ideally, all those instantiations, versions, or copies of the structure of interest would be identical. However, in reality, various of those instantiations, versions, or copies of the structure of interest can instead be aberrant, outlying, anomalous, or otherwise in some way unlike the other instantiations, versions, or copies of the structure of interest (e.g., can be misshapen, can be mispositioned).

Accordingly, an image of the specimen can be captured by a charged-particle microscope, and it can be desired to localize, via machine learning and within that image, various outlying instantiations, versions, or copies of the structure of interest. Once the outlying instantiations, versions, or copies of the structure of interest are localized, any suitable follow-on or downstream actions can then be taken (e.g., those outlying instantiations, versions, or copies of the structure of interest can be repaired or otherwise addressed in any suitable fashion, or whatever machinery was used to fabricate or manufacture the specimen can be inspected, repaired, or otherwise addressed in any suitable fashion).

As the inventors of various embodiments described herein recognized, such outlier localization can be considered as a difficult or non-trivial machine learning task.

Indeed, existing techniques facilitate such task by training, in supervised fashion, a machine learning model to selectively localize outlying versions of the structure of interest. Such supervised training relies upon training images that are annotated with respective ground-truth localizations that show or otherwise indicate where in those training images outlying versions of the structure of interest are known to be located. In other words, such supervised training can be considered as teaching the machine learning model how to visually recognize an outlying version of the structure of interest.

Unfortunately, as the present inventors realized, the machine learning model of existing techniques can learn to recognize only outlying versions of the structure of interest that are visually similar to those that are present in the training dataset. In the real-world, the specific structure of interest can vary from one operational context to the next (e.g., in one operational context, the structure of interest might be a fin fabricated on a semiconductor wafer; in another operational context, the structure of interest might instead be a trench dug into a printed circuit board; in yet another operational context, the structure of interest might be an organic plant cell or animal cell in a biological sample). Accordingly, existing techniques involve training a separate or respective machine learning model to localize outlying versions of each different type of structure of interest (e.g., a first machine learning model that is trained to localize outlying semiconductor fins; a second machine learning model that is trained to localize outlying printed circuit board trenches; a third machine learning model that is trained to localize outlying plant or animal cells). Because training of a single machine learning model can be considered as highly time-consuming and resource-intensive, training of multiple such models (e.g., one for each desired type of structure of interest) can be even more time-consuming and resource-intensive, which can be undesirable. Additionally, even when only a single type of structure of interest is considered, the present inventors realized that what constitutes an outlying or anomalous version of the specific structure of interest can vary from one operational context to the next (e.g., in one operational context, a version of the structure of interest that exhibits an anomalous size might be desired to be localized; in another operational context, a version of the structure of interest that instead exhibits an anomalous shape might be desired to be localized; in yet another operational context, a version of the structure of interest that is placed in an anomalous position or orientation might be desired to be localized). Again, existing techniques attempt to address this by training a separate or respective machine learning model to localize each desired type of outlying or anomalous characteristic of the structure of interest (e.g., a first machine learning model that is trained to localize semiconductor fins of outlying sizes; a second machine learning model that is trained to localize semiconductor fins of outlying shapes; a third machine learning model that is trained to localize semiconductor fins placed in outlying positions or orientations). As mentioned above, training of a single machine learning model can be considered as highly time-consuming and resource-intensive, and so training of multiple such models (e.g., one for each desired type of outlier of the structure of interest) can be even more time-consuming and resource-intensive, which can be undesirable. In summary, existing techniques can be considered as exhibiting significantly lowered, reduced, stunted, or otherwise inflexible outlier localization generalizability.

Accordingly, systems or techniques that can improve outlier localization generalizability for images captured by charged-particle microscopes can be desirable.

Various embodiments described herein can address this technical problem. One or more embodiments described herein can include systems, computer-implemented methods, apparatus, or computer program products that can facilitate text-conditioned anomaly detection for charged-particle microscopy images. In particular, the present inventors devised various techniques for leveraging the emerging capabilities of large language models (LLMs), such as ChatGPT, to improve or otherwise enhance the flexibility with which anomalous or outlying structures of interest are localized. Specifically, although whatever particular type of structure of interest and outlying characteristics of that structure of interest are desired to be localized can vary immensely across different operational contexts, the present inventors realized that such immense variability can, contrary to the teachings of existing techniques, be functionally spanned or captured by textual input prompts of LLMs. In other words, the present inventors realized that an LLM could be trained or configured to: receive as input not just a charged-particle microscopy image of a specimen, but also a textual prompt that linguistically describes or explains which specific structures of interest exhibiting which specific visual characteristics are desired to be localized within the specimen depicted in the charged-particle microscopy image; and produce as output a localization that indicates where in the charged-particle microscopy image such specific structures of interest (if any) are positioned. In still other words, the charged-particle microscopy image can be considered as being conditioned on or otherwise accompanied by the textual prompt. In this way, a single LLM can learn how to localize a large variety of different structures of interest and of different outlying characteristics of such structures of interest. Indeed, in some cases, a single LLM can even be able to localize specific structures that it has never properly encountered before, because the textual prompt can verbally describe such specific structures rather than referring to them by name (e.g., even if an LLM has never before encountered a “ribosome”, the LLM can nevertheless be prompted to localize ribosomes in a given image by a textual prompt that states “Find all small, dark circles in the image,” since ribosomes often appear as small, dark circles). Accordingly, various embodiments described herein can be considered as exhibiting significantly more generalizability as compared to existing techniques.

Various embodiments described herein can be considered as a computerized tool (e.g., any suitable combination of computer-executable hardware or computer-executable software) that can facilitate text-conditioned anomaly detection for charged-particle microscopy images. In various aspects, such computerized tool can comprise an access component, a scan component, or a localization component.

In various embodiments, there can be a charged-particle microscope. In various aspects, the charged-particle microscope can exhibit any suitable design or construction (e.g., can be an SEM, can be a TEM, can be a dual-beam microscope). In various instances, there can be any suitable specimen (e.g., semiconductor wafer or lamella) that is loaded in the charged-particle microscope (e.g., that is currently located or positioned on an actuatable stage of the charged-particle microscope). In various cases, the specimen can have or otherwise contain various constituent structures or objects (e.g., fins, gates, drains, nanowires, organelles).

In various embodiments, there can be an outlier identification text prompt that is associated with the charged-particle microscope. In various aspects, the outlier identification text prompt can be unstructured or plain text (e.g., natural language text) that semantically describes, explains, or otherwise identifies: a specific structure of interest that is expected to be in or on the specimen; and an outlying characteristic which might or might not be exhibited by the specific structure of interest. In various cases, the structure of interest can be repeated or duplicated, such that the specimen contains multiple instantiations of the structure of interest, and the outlying characteristic can be any suitable physical or visible anomaly or aberration that can be exhibited by a minority of those multiple instantiations of the structure of interest. Alternatively, the outlying characteristic can be any suitable physical or visible property that can be exhibited by any suitable number of those multiple instantiations of the structure of interest. In some aspects, the outlying characteristic can be absolute or relative, and can be or otherwise relate to the size, shape, position, spatial orientation, or color of the structure of interest. In various instances, the outlier identification text prompt can be typed or spoken by a user or technician via any suitable graphical user-interface (GUI) text field or microphone of the charged-particle microscope.

In various cases, it can be desired to localize within the specimen any instantiations of the structure of interest that exhibit or otherwise possess the outlying characteristic. As described herein, the computerized tool can facilitate such localization.

In various embodiments, the access component of the computerized tool can electronically access the charged-particle microscope or the outlier identification text prompt. For instance, the access component can send electronic commands to, or can receive electronic data from, the charged-particle microscope. As another instance, the access component can electronically receive or retrieve the outlier identification text prompt from the charged-particle microscope or from any suitable computerized workstation associated with the charged-particle microscope. In some cases, the access component can be considered as a conduit through which other components of the computerized tool can electronically interact with (e.g., activate, deactivate, read, write, edit, copy, manipulate) the charged-particle microscope or the outlier identification text prompt.

In various embodiments, the scan component of the computerized tool can, in response to receipt of the outlier identification text prompt, electronically cause the charged-particle microscope to scan the specimen, thereby yielding a scanned image (e.g., a two-dimensional or three-dimensional SEM scanned image, a two-dimensional or three-dimensional TEM scanned image) that depicts or illustrates at least some portion of the specimen. In other words, the scan component can electronically instruct or command the charged-particle microscope to generate the scanned image. In various instances, the scan component can cause the charged-particle microscope to perform such scanning according to any suitable default microscopy protocol that is known or deemed to be non-destructive or non-damaging for wide swaths or proportions of possible microscopy specimens. As a non-limiting example, the default microscopy protocol can involve using a default beam current (e.g., on the order of nano-amps (nA) or pico-amps (pA)) and a default beam voltage (e.g., less than 5 kilo-volts (kV)) that are sufficiently low so as to be known or expected to not damage, deteriorate, or otherwise degrade all, most, or any suitable subgroup of whatever possible specimens that the charged-particle microscope is expected or designed to encounter. In other cases, the scan component can cause the charged-particle microscope to perform such scanning according to any suitable microscopy protocol that is selected by the user or technician (e.g., such microscopy protocol can be typed or spoken by the user or technician into any suitable GUI text field or microphone of the charged-particle microscope).

In various embodiments, the localization component of the computerized tool can electronically store, maintain, control, or otherwise access an LLM. In various aspects, the LLM can exhibit any suitable deep learning internal architecture. For example, the LLM can include any suitable numbers of any suitable types of layers (e.g., input layer, one or more hidden layers, output layer, any of which can be convolutional layers, dense layers, long short-term memory (LSTM) layers, transformer layers, non-linearity layers, pooling layers, batch normalization layers, or padding layers). As another example, the LLM can include any suitable numbers of neurons in various layers (e.g., different layers can have the same or different numbers of neurons as each other). As yet another example, the LLM can include any suitable activation functions (e.g., softmax, sigmoid, hyperbolic tangent, rectified linear unit) in various neurons (e.g., different neurons can have the same or different activation functions as each other). As still another example, the LLM can include any suitable interneuron connections or interlayer connections (e.g., forward connections, skip connections, recurrent connections).

Regardless of its specific internal architecture, the LLM can be configured as a generative text model. That is, the LLM can be configured to receive as input any suitable textual data (which, in various cases, may or may not be accompanied by any suitable numerical data or any suitable graphical data), and the LLM can be configured to produce as output synthesized textual content (e.g., one or more synthesized sentences or sentence fragments), synthesized numerical content (e.g., one or more synthesized scalars or vectors), or synthesized graphical content (e.g., one or more synthesized bounding boxes or segmentation masks) that is or are semantically or substantively based on such inputted textual data (and based on accompanying numerical or graphical data, as the case may be).

In order to accomplish this, the LLM can be considered as comprising an encoder portion and a synthesizer portion. In various aspects, the encoder portion can be any suitable upstream layers of the LLM that are configured to receive the inputted textual data (and any accompanying numerical or graphical data) and to produce embeddings based on that inputted textual data. In various instances, the synthesizer portion can be any suitable downstream layers of the LLM that are configured to receive those embeddings and to produce the synthesized textual, numerical, or graphical content based on those embeddings.

In various aspects, an embedding produced by the encoder portion of the LLM in response to a piece of inputted textual, numerical, or graphical data can be considered as any suitable mathematical quantity (e.g., scalar, vector, matrix, tensor, tokenization, or any suitable combination thereof) that numerically represents at least some substantive or semantic aspect of that inputted textual, numerical, or graphical data in a low-dimensional fashion. In other words, the embedding can be smaller in terms of size or dimensionality (e.g., in some cases, one or more orders of magnitude smaller) than such inputted textual, numerical, or graphical data; but despite such smaller size, the embedding can nevertheless be considered as substantively or semantically representing such inputted textual, numerical, or graphical data. In still other words, the embedding can be considered as a latent vector representation of such inputted textual, numerical, or graphical data.

In various aspects, the localization component can electronically generate a set of outlier localizations, by executing the LLM on both the scanned image and the outlier identification text prompt. For example, the localization component can concatenate the scanned image and the outlier identification text prompt together, the localization component can feed that concatenation to the input layer of the LLM, that concatenation can complete a forward pass through the one or more hidden layers of the LLM, and the output layer of the LLM can calculate the set of outlier localizations based on activations provided by the one or more hidden layers of the LLM.

In any case, the set of outlier localizations can be any suitable electronic data that indicate (e.g., via intra-image coordinates, via bounding boxes, via segmentation masks) where, within the scanned image, instantiations of the structure of interest that exhibit the outlying characteristic are located (as inferred or predicted by the LLM). That is, the LLM can be considered as evaluating the pixels or voxels of the scanned image so as to answer or otherwise obey the outlier identification text prompt. In other words, the LLM can be considered as searching through the scanned image for pixels or voxels that the LLM believes make up or belong to versions of the structure of interest that have whatever outlying characteristic (e.g., whatever anomalous size, shape, position, orientation, or color) is verbally described in the outlier identification text prompt. In still other words, the LLM can be considered as broadening, narrowing, or otherwise tailoring its pixel or voxel search according to whatever is stated in the outlier identification text prompt. Thus, in stark contrast to existing techniques which would receive as input only the scanned image, the LLM of various embodiments described herein is not limited or restricted to only localizing one specific type of outlying characteristic of only one specific type of structure of interest. This can be considered as facilitating far more generalizable or flexible anomaly or outlier localization as compared to existing techniques.

In any case, the outlier identification text prompt can be considered as specifying a particular structure of interest and a particular outlying characteristic, and the set of outlier localizations can be considered as indicating where within the scanned image any instantiations of that particular structure of interest that exhibit that particular outlying characteristic are located (e.g., the set of outlier localizations can be considered as a substantive answer to the outlier identification text prompt). In some aspects, the localization component can electronically share or transmit the set of outlier localizations with or to any other suitable computing device. In other aspects, the localization component can electronically render the set of outlier localizations on any suitable electronic display (e.g., computer screen) associated with the charged-particle microscope. In any of these cases, the user or technician can thus be considered as being notified of the set of outlier localizations.

Note that, in order for the outlier localizations described herein to be accurately generated, the LLM should first undergo training. In various cases, the computerized tool can train the LLM using any suitable training paradigms (e.g., via supervised training, unsupervised training, or reinforcement learning), as described later herein.

Various embodiments described herein can be employed to use hardware or software to solve problems that are highly technical in nature (e.g., to facilitate text-conditioned anomaly detection for charged-particle microscopy images), that are not abstract and that cannot be performed as a set of mental acts by a human. Further, some of the processes performed can be performed by a specialized computer (e.g., electron microscopes such as SEMs, TEMs, or dual-beam microscopes; machine learning models such as LLMs) for carrying out defined acts related to the field of charged-particle microscopy.

For example, such defined acts can include: accessing, by a device operatively coupled to a processor, an image captured by a charged-particle microscope, wherein the image depicts a specimen; and localizing, by the device, one or more outlying instantiations of a structure of interest of the specimen, based on feeding both the image and a text prompt to a large language model. In various aspects, the text prompt can comprise one or more sentences or sentence fragments that semantically define or describe the one or more outlying instantiations. In various instances, the one or more sentences or sentence fragments can semantically define or describe the one or more outlying instantiations in terms of their sizes with respect to other instantiations of the structure of interest. In various cases, the one or more sentences or sentence fragments can semantically define or describe the one or more outlying instantiations in terms of their shapes with respect to other instantiations of the structure of interest. In various aspects, wherein the one or more sentences or sentence fragments can semantically define or describe the one or more outlying instantiations in terms of their distances from other instantiations of the structure of interest. In various instances, the one or more sentences or sentence fragments can semantically define or describe the one or more outlying instantiations in terms of their arrangements (e.g., above, below, leftward of, rightward of, touching) with respect to other instantiations of the structure of interest. In various cases, the one or more sentences or sentence fragments can semantically define or describe the one or more outlying instantiations in terms of their intensities (e.g., average pixel intensity values) with respect to other instantiations of the structure of interest.

Such defined acts are inherently computerized. Indeed, a charged-particle microscope (e.g., SEM, TEM, dual beam microscope) is a highly-technical computerized device comprising specific computerized hardware (e.g., temperature sensors, pressure sensors, voltage sensors, ion beam emitters, electron beam emitters, focusing lenses, ion detectors, electron detectors, beam apertures, fluid valves, actuatable specimen stages). A charged-particle microscope and the images that it captures cannot be implemented by the human mind, or by a human with pen and paper, in any reasonable or practicable way without computers. Furthermore, artificial neural networks (e.g., LLMs) are also inherently computerized constructs comprising specific software-oriented architectures (e.g., input layers, hidden layers, or output layers, any of which can be made up of trainable or non-trainable internal parameters such as convolutional layers or LSTM layers). Artificial neural networks cannot be trained or executed by the human mind, or by humans with mere pen and paper, in any reasonable or practicable way without computers. Further still, outlier localization is an inherently computerized task that focuses on enabling computers to automatically locate visible structural anomalies within charged-particle microscopy images. It would make no sense whatsoever to discuss charged-particle microscopy outlier localization outside of a computerized context.

Moreover, various embodiments described herein can integrate into a practical application various teachings relating to the field of charged-particle microscopy. As explained above, existing techniques for facilitating outlier or anomaly localization for charged-particle microscopy images train a separate machine learning model for each distinct type of structure of interest for which localization is desired (e.g., one machine learning model for localizing transistor fins, another machine learning model for localizing transistor gates, yet another machine learning model for localizing nanowires). Since different operational contexts can involve localizing different types of structures of interest, such existing techniques can require that very many different machine learning models be trained, which can be excessively time-consuming and resource-intensive. Even for only a single type of structure of interest (e.g., transistor fins), existing techniques train a separate machine learning model for each distinct outlying characteristic of that single type of structure of interest for which localization is desired (e.g., one machine learning model for localizing transistor fins that have outlying sizes; another machine learning model for localizing transistor fins that have outlying shapes; yet another machine learning model for localizing transistor fins that are located in outlying positions). This can further exacerbate the time-consuming and resource-intensive costs associated with existing techniques.

Various embodiments described herein can help to ameliorate this technical problem, by implementing text-conditioned anomaly detection for charged-particle microscopy images. Indeed, various embodiments described herein can involve obtaining a textual prompt whose sentences or sentence fragments describe or otherwise define a particular structure of interest and a particular outlying characteristic of that particular structure of interest. So, when given an image of a specimen, various embodiments described herein can involve executing on both that given image and the textual prompt an LLM. Because the textual prompt can be considered as a localization instruction, such execution can cause the LLM to locate (e.g., via bounding boxes or segmentation masks) within the given image whichever instantiations of the particular structure of interest which the LLM infers exhibit the particular outlying characteristic. Note that changing the content of the textual prompt can commensurately change what is localized in the given image by the LLM. Accordingly, the LLM can be considered as not being limited or restricted to localizing only a single type of structure of interest that exhibits a single type of outlying characteristic. Instead, the LLM can be flexible or generalizable across a wide range of structures of interest or outlying characteristics. In fact, the LLM can even be able to reliably or accurately localize structures of interest that it had never encountered during training. This can be accomplished by describing such a never-before-encountered structure of interest using easier words that the LLM likely has encountered before rather than complicated technical jargon. As a non-limiting example, suppose that the LLM has never before learned the term “plant cell” and that it is desired for the largest plant cell in the given image to be localized. In such case, the LLM likely would not perform reliably or accurately if the textual prompt stated: “Find the largest plant cell in the given image.” However, despite such lack of experience, the LLM likely would perform reliably or accurately if the textual prompt instead stated: “Find the largest rectangular object in the given image.” That is, the LLM's lack of experience or training with respect to the more complicated term “plant cell” can be overcome by instead using the easier-to-understand term “rectangular object” (e.g., plant cells often appear in scanned images as being rectangular, and the LLM can be likely to have learned what “rectangular object” means notwithstanding never having learned what “plant cell” means). In stark contrast, if a machine learning model of existing techniques had never before encountered or localized a plant cell, the only way to rectify such lack of experience would be time-consuming retraining. For at least the above reasons, various embodiments described herein can be considered as addressing or ameliorating various problems or disadvantages that afflict existing techniques for facilitating anomaly localization with respect to charged-particle microscopy (e.g., text-conditioning allows various embodiments described herein to exhibit far more generalizability or flexibility than existing techniques). Therefore, various embodiments described herein can be considered as a concrete and tangible technical improvement in the field of charged-particle microscopy. Accordingly, various embodiments described herein certainly qualify as useful and practical applications of computers.

Furthermore, various embodiments described herein can control real-world tangible devices based on the disclosed teachings. For example, various embodiments described herein can electronically activate, deactivate, or otherwise actuate real-world hardware (e.g., ion beam emitters, ion focusing lenses, carrier fluid valves/pumps) of real-world charged-particle microscopes (e.g., SEMs, TEMs, dual-beam microscopes).

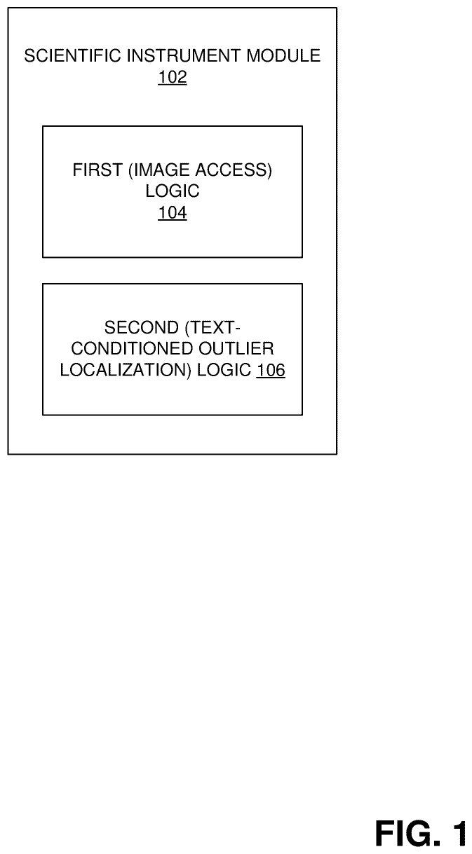

FIG. 1 illustrates an example, non-limiting block diagram of a scientific instrument module 102 in accordance with various embodiments described herein.

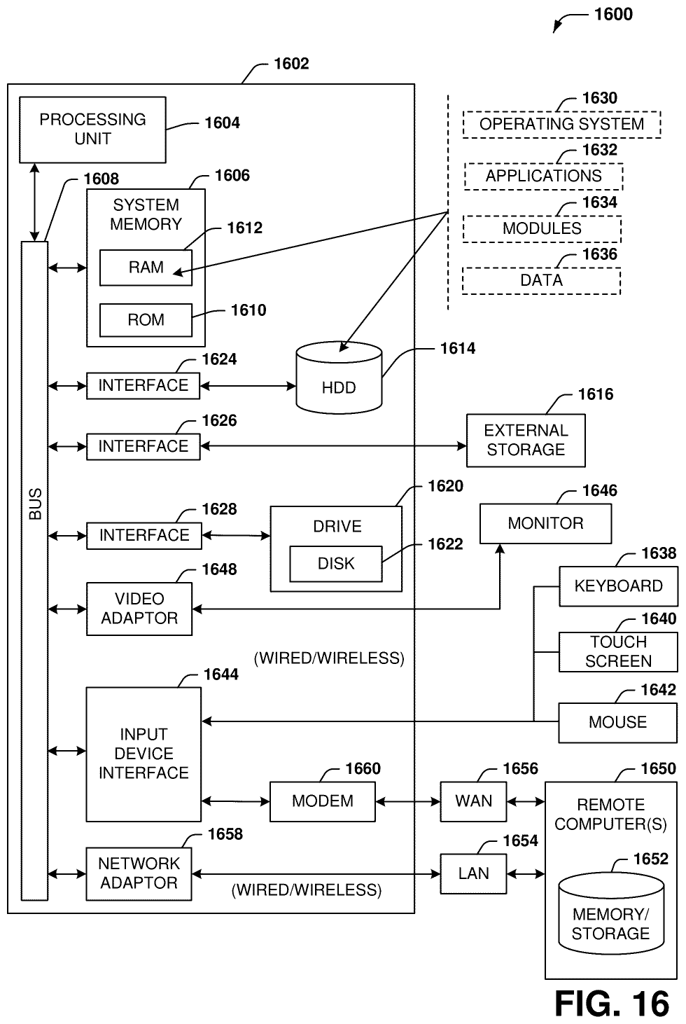

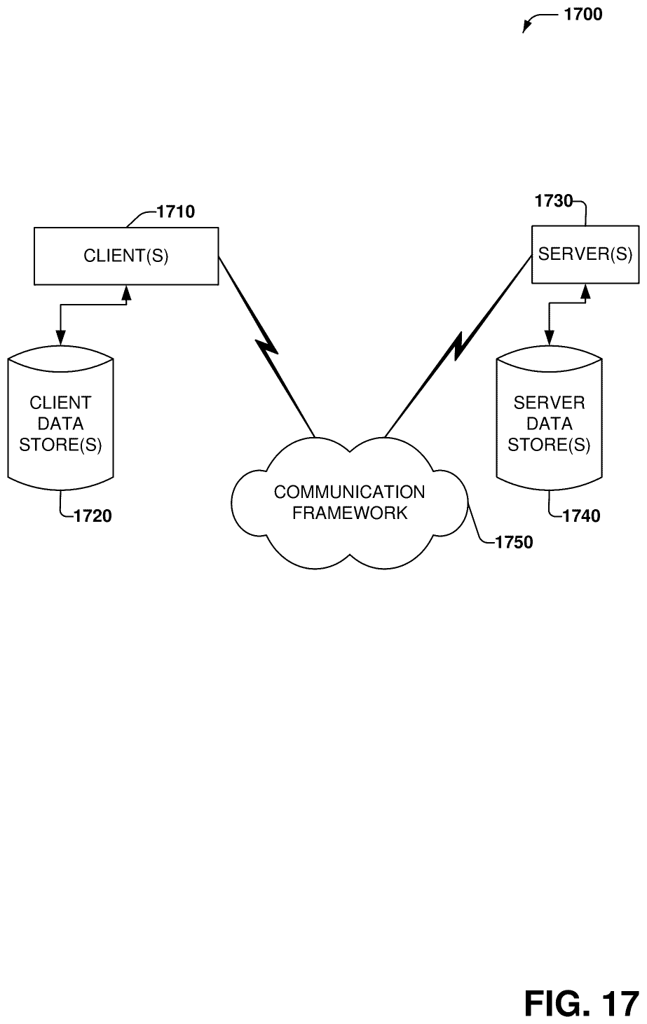

In various embodiments, the scientific instrument module 102 can be implemented by circuitry (e.g., including electrical or optical components), such as a programmed computing device. Logic of the scientific instrument module 102 can be included in a single computing device or can be distributed across multiple computing devices that are in communication with each other as appropriate. Examples of computing devices that may, singly or in combination, implement the scientific instrument module 102 are discussed herein with reference to FIG. 16, and examples of systems or networks of interconnected computing devices, in which the scientific instrument module 102 may be implemented across one or more of the computing devices, are discussed herein with reference to FIG. 17.

The scientific instrument module 102 can include first logic 104 and second logic 106. As used herein, the term “logic” can include an apparatus that is to perform a set of operations associated with the logic. For example, any of the logic elements included in the scientific instrument module 102 can be implemented by one or more computing devices programmed with instructions to cause one or more processing devices of the computing devices to perform the associated set of operations. In a particular embodiment, a logic element may include one or more non-transitory computer-readable media having instructions thereon that, when executed by one or more processing devices of one or more computing devices, cause the one or more computing devices to perform the associated set of operations. As used herein, the term “module” can refer to a collection of one or more logic elements that, together, perform a function associated with the module. Different ones of the logic elements in a module may take the same form or may take different forms. For example, some logic in a module may be implemented by a programmed general-purpose processing device, while other logic in a module may be implemented by an application-specific integrated circuit (ASIC). In another example, different ones of the logic elements in a module may be associated with different sets of instructions executed by one or more processing devices. A module can omit one or more of the logic elements depicted in the associated drawings; for example, a module may include a subset of the logic elements depicted in the associated drawings when that module is to perform a subset of the operations discussed herein with reference to that module.

In various embodiments, there can be a scientific instrument corresponding to the scientific instrument module 102. In various aspects, the scientific instrument can be any suitable computerized device that can electronically measure some scientifically-relevant, clinically-relevant, or research-relevant characteristic, property, or attribute of an analytical specimen (e.g., of a known or unknown mixture, compound, or collection of matter). As a non-limiting example, a scientific instrument can be a scanning electron microscope. In such case, the scientific instrument can capture images of the analytical specimen, so as to measure or determine a surface topography, a surface material composition, or a crystallographic structure of the analytical specimen. As another non-limiting example, a scientific instrument can be a transmission electron microscope. In such case, the scientific instrument can capture images of the interior of the analytical specimen, so as to measure or determine interior structural details of the analytical specimen. As even another non-limiting example, a scientific instrument can be a dual beam microscope. In such case, the scientific instrument can capture images of the analytical specimen in addition to being able to mill the analytical specimen. As a more general non-limiting example, a scientific instrument can be any suitable type of charged-particle microscope (e.g., some types of microscopes can use beams of non-electron ions to capture images).

In various embodiments, the first logic 104 can access an image captured or generated by the scientific instrument. In various aspects, the image can depict any suitable analytical specimen.

In various embodiments, the second logic 106 can involve localizing one or more outlying instantiations of a structure of interest of the analytical specimen, based on feeding both the image and a text prompt to an LLM. More specifically, the text prompt can be or contain sentences or sentence fragments that semantically or linguistically describe, explain, or otherwise define the one or more outlying instantiations (e.g., that specify what the structure of interest is and what physical or visible characteristics make an instantiation of the structure of interest an outlier). In any case, the second logic 106 can involve executing the LLM on both the image and the text prompt. In various aspects, such execution can cause the LLM to produce as output localizations (e.g., bounding boxes, segmentation masks, pixel coordinates) that show where in the image the one or more outlying instantiations are positioned or located. Note that the LLM can be considered as being conditioned not just on the image but also on the text prompt. Thus, by changing the semantic content (e.g., the words or phrases) of the text prompt, the LLM can be forced to localize different types of structures of interest exhibiting different outlying physical characteristics. In this way, a single machine learning model (e.g., the LLM) can be able to facilitate anomaly or outlier localization across different structures of interest, unlike existing techniques.

Accordingly, the scientific instrument module 102 can facilitate text-conditioned anomaly detection for charged-particle microscopy images.

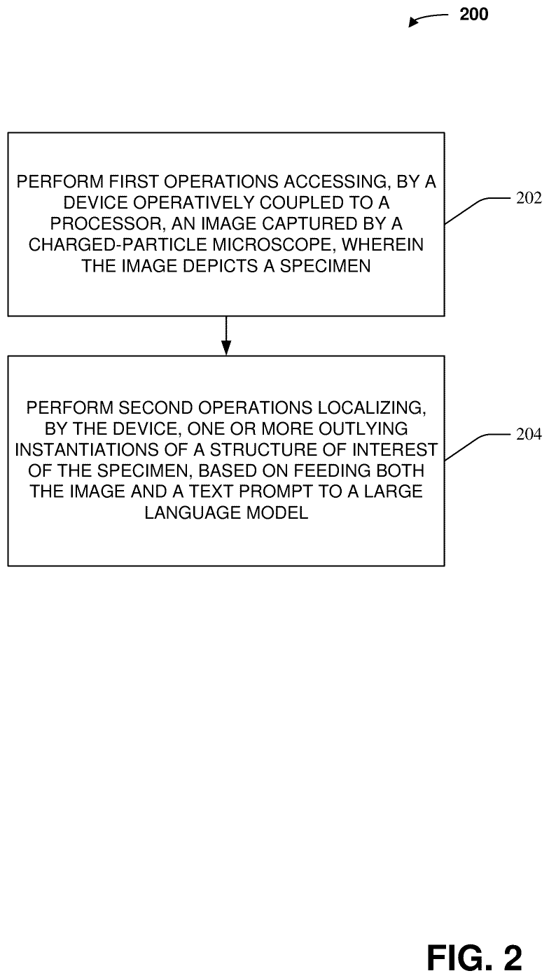

FIG. 2 is an example, non-limiting flow diagram of a computer-implemented method 200 in accordance with various embodiments described herein. The operations of the computer-implemented method 200 may be used in any suitable context to perform any suitable operations (e.g., can be performed by or used in conjunction with any of the various modules, computing devices, or graphical user interfaces described with respect to FIGS. 16-17. Operations are illustrated once each and in a particular order in FIG. 2, but the operations may be reordered or repeated as desired and appropriate (e.g., different operations performed may be performed in parallel, as suitable).

In various aspects, act 202 can include performing first operations accessing, by a device operatively coupled to a processor, an image captured by a charged-particle microscope, wherein the image can depict an analytical specimen. In various cases, the first logic 104 can perform or otherwise facilitate act 202.

In various aspects, act 204 can include performing second operations localizing, by the device, one or more outlying instantiations of a structure of interest of the specimen, based on feeding both the image and a text prompt to a large language model. In various instances, the second logic 106 can perform or otherwise facilitate act 204.

Accordingly, the computer-implemented method 200 can facilitate text-conditioned anomaly detection for charged-particle microscopy images.

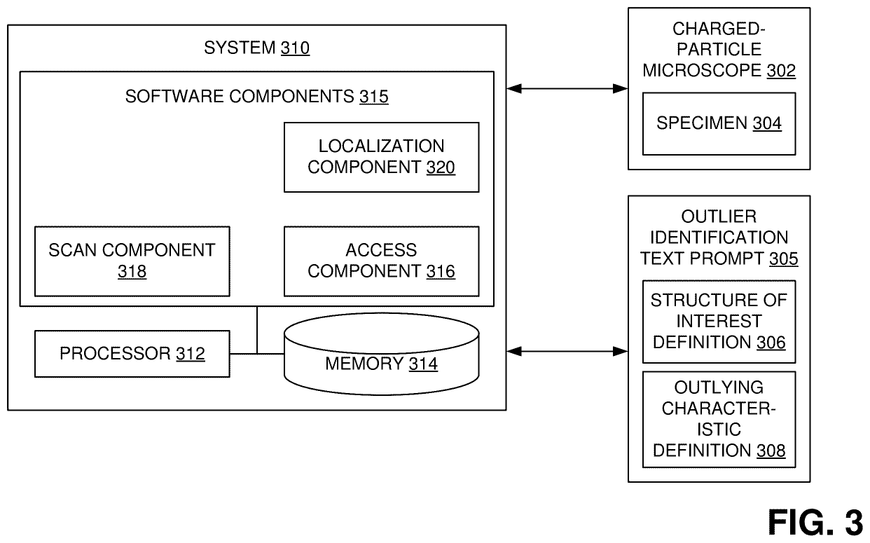

FIG. 3 illustrates a block diagram of an example, non-limiting system that can facilitate text-conditioned anomaly detection for charged-particle microscopy images in accordance with one or more embodiments described herein.

In various embodiments, there can be a charged-particle microscope 302. In various aspects, the charged-particle microscope 302 can be as described above. That is, the charged-particle microscope 302 can be any suitable computerized device that can leverage its constituent hardware (e.g., electron sources, anodes, condenser lenses, condenser apertures, scan coils, objective lenses, objective apertures, deflectors, condensers, stigmators, electron detectors, X-ray detectors, actuatable specimen stages) to electronically capture any suitable image of any suitable analytical specimen. As a non-limiting example, the charged-particle microscope 302 can be any suitable SEM. As another non-limiting example, the charged-particle microscope 302 can be any suitable TEM. As yet another non-limiting example, the charged-particle microscope 302 can be any suitable dual-beam microscope.

Although not explicitly shown in the figures, the charged-particle microscope 302 can be electronically integrated with any suitable human-computer interface device, which can be remote from or local to the charged-particle microscope 302. Accordingly, a user or technician associated with the charged-particle microscope 302 can interact with or otherwise control the charged-particle microscope 302. Some non-limiting examples of the human-computer interface device can be a keyboard of the charged-particle microscope 302, a keypad of the charged-particle microscope 302, a touchscreen of the charged-particle microscope 302, or a voice-command system of the charged-particle microscope 302.

Although not explicitly shown in the figures, the charged-particle microscope 302 can comprise a plurality of configurable operating settings. In various aspects, each of the plurality of configurable operating settings can be any suitable hardware-related characteristic or software-related characteristic of the charged-particle microscope 302 that can guide, affect, or otherwise dictate how the charged-particle microscope 302 runs, operates, or functions with respect to any given analytical specimen and that can be selectively controlled, changed, adjusted, or otherwise set by the user or technician (e.g., via interaction with the human-computer interface device of the charged-particle microscope 302). As a non-limiting example, any of the plurality of configurable operating settings can be a user-controllable electric voltage setting (e.g., beam voltage) or electric current setting (e.g., beam current), which can allow the user or technician to selectively control an electrode of the charged-particle microscope 302, so as to selectively increase or decrease an electric voltage or electric current within, or that is applied by, the charged-particle microscope 302. As another non-limiting example, any of the plurality of configurable operating settings can be a user-controllable temperature setting, which can allow the user or technician to control a heater (e.g., stage heater, heating coil) or cooler (e.g., cooling fan, heat pump, refrigerator) of the charged-particle microscope 302, so as to selectively increase or decrease a temperature within, or that is applied by, the charged-particle microscope 302. As still another non-limiting example, any of the plurality of configurable operating settings can be a user-controllable mechanical actuator setting, which can allow the user or technician to control a mechanical actuator (e.g., electric motor, specimen stage, iris aperture, fluid pump or syringe) of the charged-particle microscope 302, so as to selectively move the mechanical actuator. As yet another non-limiting example, any of the plurality of configurable operating settings can be a user-controllable optics setting, which can allow the user or technician to control an optical element (e.g., optical lens, optical deflector) of the charged-particle microscope 302, so as to selectively change an optical quality (e.g., focal spot size or location, astigmatism, defocus) that is applied by the charged-particle microscope 302.

In various instances, the charged-particle microscope 302 can be loaded with a specimen 304. As a non-limiting example, the specimen 304 can be presently positioned, located, or otherwise affixed onto the specimen stage of the charged-particle microscope 302, such that the specimen 304 is analyzable or scannable by the charged-particle microscope 302. In various cases, the specimen 304 can be any suitable type of synthetic sample or naturally-occurring sample that can exhibit any suitable physical, chemical, compositional, or other properties, attributes, or characteristics. In various aspects, the specimen 304 can be manufactured by any suitable microfabrication or nanofabrication techniques, such as etching, milling, or deposition. As a non-limiting example, the specimen 304 can be a lamella taken from a semiconductor substrate or wafer. As another non-limiting example, the specimen 304 can be any other suitable integrated circuit element or printed circuit board element. However, in other cases, the specimen 304 can be an organic or biological sample (e.g., a tissue sample).

In various aspects, the specimen 304 can comprise any suitable number of any suitable types of structures of interest. In various aspects, a structure of interest can be any suitable physical thing that is a discrete, constituent part or portion of the specimen. As a non-limiting example, a structure of interest can be a transistor gate that is fabricated in or on the specimen 304. As another non-limiting example, a structure of interest can be a transistor fin that is fabricated in or on the specimen 304. As still another non-limiting example, a structure of interest can be a transistor drain that is fabricated in or on the specimen 304. As yet another non-limiting example, a structure of interest can be a nanowire that is fabricated in or on the specimen 304. As even another non-limiting example, a structure of interest can be a cellular nucleus or other organelle that has grown within or on the specimen 304. In various instances, any structure of interest can be repeated or duplicated any suitable number of times on or in the specimen 304. Accordingly, the specimen 304 can be considered as comprising multiple distinct versions, copies, or instantiations of any given structure of interest.

In various embodiments, there can be an outlier identification text prompt 305. In various aspects, the outlier identification text prompt 305 can comprise a structure of interest definition 306 or an outlying characteristic definition 308.

In various instances, the structure of interest definition 306 can be any suitable number of plain text, natural language, or unstructured sentences or sentence fragments that semantically, grammatically, or otherwise linguistically specify, explain, describe, indicate, or otherwise define a structure of interest that is desired to be localized in or on the specimen 304. For ease of explanation, whatever structure of interest that is indicated or described by the structure of interest definition 306 can be referred to as the specified structure of interest.

In various cases, the outlying characteristic definition 308 can be any suitable number of plain text, natural language, or unstructured sentences or sentence fragments that semantically, grammatically, or otherwise linguistically specify, explain, describe, indicate, or otherwise define a particular physical or visible characteristic, attribute, or property which might or might not be exhibited or possessed by any given instantiation of the specified structure of interest and which is desired to be localized in or on the specimen 304. For ease of explanation, whatever particular physical or visible characteristic, attribute, or property that is indicated or described by the outlying characteristic definition 308 can be referred to as the specified outlying characteristic.

In some instances, the specified outlying characteristic can be or otherwise relate to an absolute physical size of an instantiation of the specified structure of interest (e.g., the outlying characteristic definition 308 can state that the specified outlying characteristic is a physical length of at least l micrometers, for any suitable positive real number l). In other instances, the specified outlying characteristic can be or otherwise relate to a relative physical size of an instantiation of the specified structure of interest as compared to other present instantiations of the specified structure of interest (e.g., the outlying characteristic definition 308 can state that the specified outlying characteristic is an area that is at least p percent smaller than the average area exhibited by neighboring instantiations of the specified structure of interest, for any suitable positive real number p).

In some cases, the specified outlying characteristic can be or otherwise relate to an absolute physical shape of an instantiation of the specified structure of interest (e.g., the outlying characteristic definition 308 can state that the specified outlying characteristic is an ellipticity of at least k units, for any suitable positive real number k). In other cases, the specified outlying characteristic can be or otherwise relate to a relative physical shape of an instantiation of the specified structure of interest as compared to other present instantiations of the specified structure of interest (e.g., the outlying characteristic definition 308 can state that the specified outlying characteristic is an ellipticity that is at least j percent larger than the ellipticity exhibited by a nearest neighboring instantiation of the specified structure of interest, for any suitable positive real number j).

In some aspects, the specified outlying characteristic can be or otherwise relate to an absolute physical distance that separates an instantiation of the specified structure of interest from other present instantiations of the specified structure of interest (e.g., the outlying characteristic definition 308 can state that the specified outlying characteristic is being separated from neighboring instantiations of the specified structure of interest by at least q nanometers, for any suitable positive real number q). In other aspects, the specified outlying characteristic can be or otherwise relate to a relative physical distance that separates an instantiation of the specified structure of interest from other present instantiations of the specified structure of interest (e.g., the outlying characteristic definition 308 can state that the specified outlying characteristic is being separated from neighboring instantiations of the specified structure of interest by a minimum or shortest distance).

In some instances, the specified outlying characteristic can be or otherwise relate to an absolute physical arrangement or layout of instantiations of the specified structure of interest (e.g., the outlying characteristic definition 308 can state that the specified outlying characteristic is being positioned in an upper-right quadrant of the specimen 304). In other aspects, the specified outlying characteristic can be or otherwise relate to a relative physical arrangement or layout of instantiations of the specified structure of interest in comparison to other structures of interest of the specimen 304 (e.g., the outlying characteristic definition 308 can state that the specified outlying characteristic is being the fourth instantiation of the specified structure of interest when counting downwards from a top of the specimen 304).

In some cases, the specified outlying characteristic can be or otherwise relate to an absolute color or visible intensity of an instantiation of the specified structure of interest (e.g., the outlying characteristic definition 308 can state that the specified outlying characteristic is a brightness of less than r units, for any suitable positive real number r). In other cases, the specified outlying characteristic can be or otherwise relate to a relative physical color or visible intensity of an instantiation of the specified structure of interest as compared to other present instantiations of the specified structure of interest (e.g., the outlying characteristic definition 308 can state that the specified outlying characteristic is being the brightest instantiation of the specified structure of interest).

Accordingly, the outlier identification text prompt 305 can, in various aspects, be considered as a natural language request (e.g., in the case of interrogative sentences) or a natural language command (e.g., in the case of imperative sentences) that one or more instantiations, versions, or copies of the specified structure of interest which each exhibit the specified outlying characteristic be localized in or on the specimen 304. In other words, the outlier identification text prompt 305 can be considered as a natural language request or command that it be determined where in or on the specimen 304 an instantiation of the specified structure having the specified outlying characteristic is located.

In various instances, the outlier identification text prompt 305 can be provided or inputted by the user or technician of the charged-particle microscope 302 via any suitable human-computer interface device associated with the charged-particle microscope 302. As a non-limiting example, the user or technician can type (e.g., via a keyboard, keypad, or touchscreen) the outlier identification text prompt 305 into any suitable GUI text field of the charged-particle microscope 302 or of a computerized workstation that assists or is paired with the charged-particle microscope 302. As another non-limiting example, the user or technician can verbally speak into any suitable microphone of the charged-particle microscope 302 or of a computerized workstation that assists or is paired with the charged-particle microscope 302, and any suitable speech-to-text transcription system, service, or technique can convert the spoken words of the user or technician into the outlier identification text prompt 305.

In various instances, it can be desired to localize in or on the specimen 304 whichever instantiations of the specified structure of interest that exhibit the specified outlying characteristic. In various cases, a system 310, which can be electronically integrated (e.g., via any suitable wired or wireless electronic connections) with the charged-particle microscope 302 or with the outlier identification text prompt 305, can accomplish such localization as described herein.

In various aspects, the system 310 can comprise a processor 312 (e.g., computer processing unit, microprocessor) and a non-transitory computer-readable memory 314 that is operably or operatively or communicatively connected or coupled to the processor 312. The non-transitory computer-readable memory 314 can store computer-executable instructions which, upon execution by the processor 312, can cause the processor 312 or other components of the system 310 (e.g., access component 316, scan component 318, localization component 320) to perform one or more acts. In various embodiments, the non-transitory computer-readable memory 314 can store computer-executable components (e.g., access component 316, scan component 318, localization component 320), and the processor 312 can execute the computer-executable components.

In various embodiments, the system 310 can comprise an access component 316. In various aspects, the access component 316 can electronically access the charged-particle microscope 302. That is, the access component 316 can electronically communicate or otherwise electronically interact with (e.g., transmit electronic instructions or commands to, receive electronic data from) the charged-particle microscope 302. Accordingly, the access component 316 can be considered as a proxy or conduit through which other components of the system 310 can interact with, communicate with, or otherwise manipulate the charged-particle microscope 302. In various instances, the access component 316 can electronically access the outlier identification text prompt 305. That is, the access component 316 can electronically receive, electronically retrieve, or otherwise electronically obtain the outlier identification text prompt 305, from any suitable electronic source or database (e.g., possibly from the charged-particle microscope 302 or from an associated computerized workstation). In any case, the access component 316 can be considered as a proxy or conduit through which other components of the system 310 can interact with, control, or otherwise manipulate the outlier identification text prompt 305. However, these are mere non-limiting examples. In other cases, the access component 316 can be omitted, and any other components of the system 310 can communicate or interact directly with the charged-particle microscope 302 or with the outlier identification text prompt 305.

In various embodiments, the system 310 can comprise a scan component 318. In various aspects, the scan component 318 can, as described herein, cause the charged-particle microscope 302 to capture an image of the specimen 304.

In various embodiments, the system 310 can comprise a localization component 320. In various instances, the localization component 320 can, as described herein, localize whatever instantiations of the specified structure of interest that exhibit the specified outlying characteristic are in or on the specimen 304, by executing a large language model (LLM) on both the image and the outlier identification text prompt 305.

Note that, in various instances, the access component 316, the scan component 318, and the localization component 320 can collectively be considered as being one or more software components 315 of the system 310. In various aspects, it should be appreciated that the one or more software components 315 are described primarily herein as comprising three components (e.g., the access component 316, the scan component 318, and the localization component 320) for ease of explanation and illustration. However, the one or more software components 315 are not limited to being implemented as exactly such three components in every embodiment. Indeed, in some embodiments, the functionalities described herein of such three components can be combined in any suitable fashions, so as to be implemented in or by fewer than three components (e.g., in some cases, a single component can perform all of the functionalities that are described herein with respect to the access component 316, the scan component 318, and the localization component 320). In other embodiments, the functionalities described herein of such three components can instead be distributed, separated, split, or fragmented in any suitable fashions, so as to be implemented in or by more than three components (e.g., two or more components can facilitate the functionalities that are performable by the access component 316; two or more components can facilitate the functionalities that are performable by the scan component 318; two or more components can facilitate the functionalities that are performable by the localization component 320).

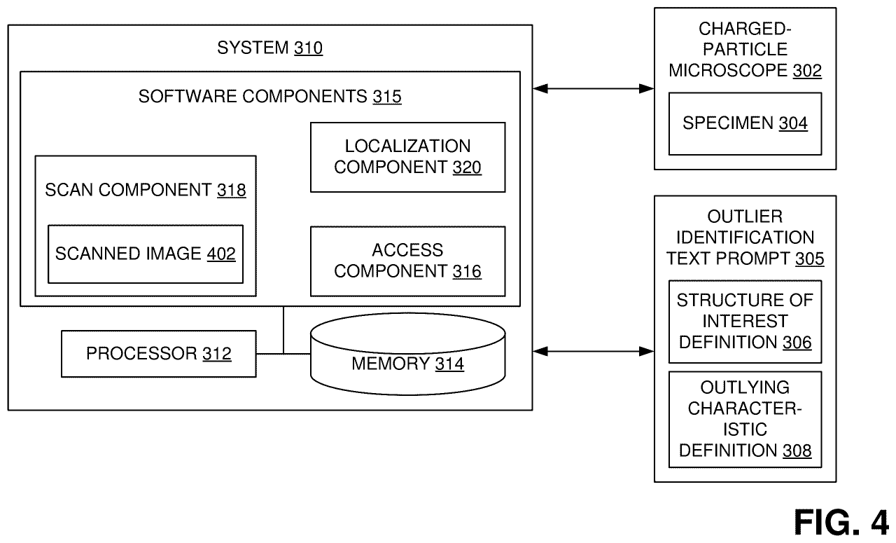

FIG. 4 illustrates a block diagram of an example, non-limiting system including a scanned image that can facilitate text-conditioned anomaly detection for charged-particle microscopy images in accordance with one or more embodiments described herein.

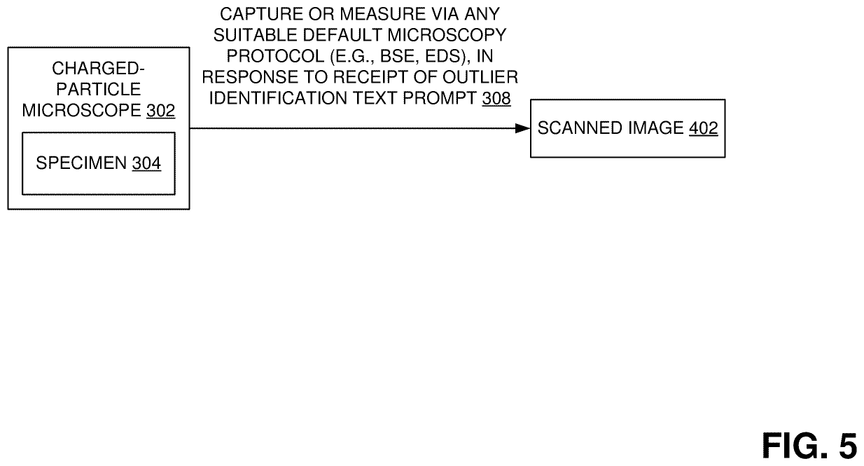

In various embodiments, the scan component 318 can, in response to electronic receipt or electronic accessing of the outlier identification text prompt 305, electronically cause the charged-particle microscope 302 to capture or otherwise generate a scanned image 402 of the specimen 304. Various non-limiting aspects are described with respect to FIG. 5.

FIG. 5 illustrates an example, non-limiting block diagram showing how the scanned image 402 can be obtained in accordance with one or more embodiments described herein.

In various embodiments, the scan component 318 can, in response to receipt or accessing of the outlier identification text prompt 305, electronically instruct or electronically command the charged-particle microscope 302 to scan the specimen 304.

In various aspects, such scanning can be in accordance with any suitable default microscopy protocol that is implementable by the charged-particle microscope 302 and that is known or expected to be non-destructive with respect to all, most, many, or any suitable subset of whatever population of specimens that the charged-particle microscope 302 might potentially encounter in clinical, scientific, or laboratory fields. In other words, the default microscopy protocol can be any suitable microscopy scan in which any of the configurable operating settings of the charged-particle microscope 302 are set, changed, or adjusted to any suitable default values or states that are known or expected to be safe for wide swaths of potential or possible specimens. As some non-limiting examples, the default microscopy protocol can involve a beam current setting, a beam voltage setting, and a stage temperature setting of the charged-particle microscope 302 being set, changed, or adjusted to any suitable default amperage, voltage, and temperature values that are known or expected to not damage, harm, or deteriorate most potential specimens. For instance, the beam voltage, beam current, and stage temperature of the default microscopy protocol can be set, changed, or adjusted to whatever low, threshold, or otherwise non-extreme values are widely recognized to not harm many specimens (e.g., if it is known or expected that most or many different types of specimens are not harmed by beam voltages below 10 kV, then the default microscopy protocol can have a beam voltage setting that is set to any suitable value below 10 kV; if it is known or expected that most or many different types of specimens are not harmed by beam currents below 0.1 nA, then the default microscopy protocol can have a beam current setting that is set to any suitable value below 0.1 nA; if it is known or expected that most or many different types of specimens are not harmed by stage temperatures of 300 Kelvin (K), then the default microscopy protocol can have a stage temperature setting that is set to 300 K).

In various instances, such scanning can instead be in accordance with any suitable microscopy protocol that is defined or otherwise selected by a user or technician of the charged-particle microscope 302. As a non-limiting example, the user or technician that provides the outlier identification text prompt 305 can select (e.g., via any suitable user-interface devices of the charged-particle microscope 302 or of an associated computerized workstation) any suitable values or states for any of the configurable operating settings of the charged-particle microscope 302, and the charged-particle microscope 302 can accordingly scan the specimen 304 using such selected values or states.

In any case, such scanning can yield or otherwise result in the scanned image 402. In various instances, the scanned image 402 can visually depict or illustrate the specimen 304, or any portion thereof, in any suitable fashion. In some cases, the scanned image 402 can be an x-by-y array of pixels, for any suitable positive integers x and y. In other cases, the scanned image 402 can be an x-by-y-by-z array of voxels, for any suitable positive integers x, y, and z. In various aspects, the visual qualities or appearance (e.g., brightness, contrast, resolution, colors) of the scanned image 402 can vary with or otherwise depend upon the microscopy protocol (e.g., default or user-selected) that is implemented by the charged-particle microscope 302 (e.g., can depend upon the default or user-selected values or states of the configurable operating settings that the charged-particle microscope 302 uses to scan the specimen 304). As a non-limiting example, the default microscopy protocol can be any suitable type of backscattered electron detection (BSE) scan. In such case, the scanned image 402 can be considered as capturing, conveying, or otherwise representing various crystallographic, topographic, or magnetic field information regarding the specimen 304. As another non-limiting example, the default microscopy protocol can be any suitable type of electron backscatter diffraction (EBSD) scan. In such case, the scanned image 402 can be considered as capturing, conveying, or otherwise representing various crystalline structure or orientation information regarding the specimen 304. As even another non-limiting example, the default microscopy protocol can be any suitable cathodoluminescence scan. In such case, the scanned image 402 can be considered as capturing, conveying, or otherwise representing high-resolution topographic information regarding luminescent portions (if any) of the specimen 304.

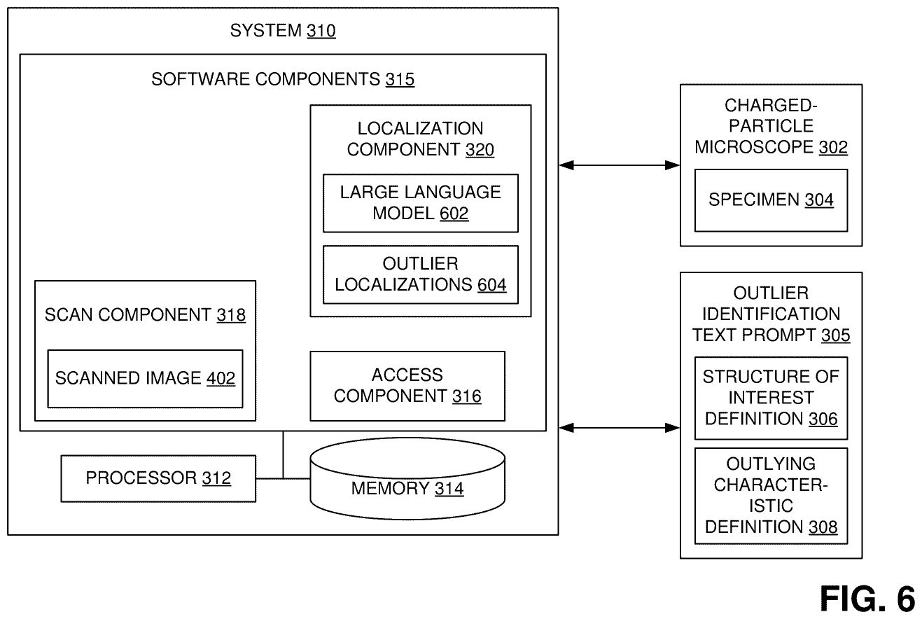

FIG. 6 illustrates a block diagram of an example, non-limiting system including a large language model and a set of outlier localizations that can facilitate text-conditioned anomaly detection for charged-particle microscopy images in accordance with one or more embodiments described herein.

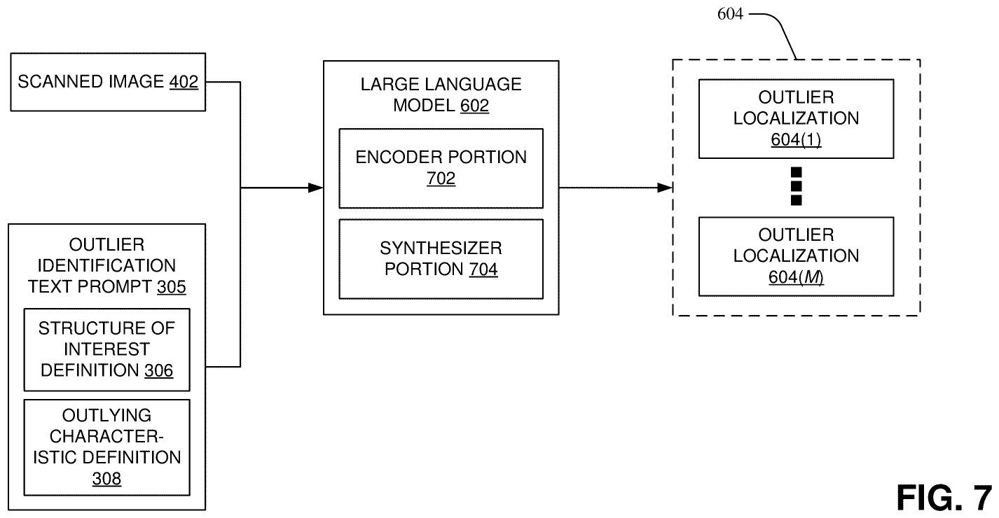

In various embodiments, the localization component 320 can electronically store, electronically maintain, electronically control, or otherwise electronically access a large language model 602 (hereafter “LLM 602”). In various aspects, the localization component 320 can leverage the LLM 602, so as to generate a set of outlier localizations 604. Non-limiting details are described with respect to FIG. 7.

FIG. 7 illustrates an example, non-limiting block diagram showing how the set of outlier localizations 604 can be obtained via the LLM 602 in accordance with one or more embodiments described herein.

In various aspects, the LLM 602 can comprise an encoder portion 702 and a synthesizer portion 704. In various cases, the encoder portion 702 can be considered as being upstream from the synthesizer portion 704. Equivalently, the synthesizer portion 704 can be considered as being downstream of the encoder portion 702.

In various aspects, the encoder portion 702 can exhibit any suitable deep learning internal architecture. Indeed, in various cases, the encoder portion 702 can have an input layer, one or more hidden layers, and an output layer. In various instances, any of such layers can be coupled together by any suitable interneuron connections or interlayer connections, such as forward connections, skip connections, or recurrent connections. Furthermore, in various cases, any of such layers can be any suitable types of neural network layers having any suitable learnable or trainable internal parameters. For example, any of such input layer, one or more hidden layers, or output layer can be convolutional layers, whose learnable or trainable parameters can be convolutional kernels. As another example, any of such input layer, one or more hidden layers, or output layer can be dense layers, whose learnable or trainable parameters can be weight matrices or bias values. As still another example, any of such input layer, one or more hidden layers, or output layer can be batch normalization layers, whose learnable or trainable parameters can be shift factors or scale factors. As even another example, any of such input layer, one or more hidden layers, or output layer can be LSTM layers, whose learnable or trainable parameters can be input-state weight matrices or hidden-state weight matrices. As yet another example, any of such input layer, one or more hidden layers, or output layer can be transformer layers, whose learnable or trainable parameters can be single-head or multi-head attention blocks or other weight matrices. Further still, in various cases, any of such layers can be any suitable types of neural network layers having any suitable fixed or non-trainable internal parameters. For example, any of such input layer, one or more hidden layers, or output layer can be non-linearity layers, padding layers, pooling layers, or concatenation layers.

Likewise, in various instances, the synthesizer portion 704 can exhibit any suitable deep learning internal architecture. Indeed, in various cases, the synthesizer portion 704 can have an input layer, one or more hidden layers, and an output layer. In various instances, any of such layers can be coupled together by any suitable interneuron connections or interlayer connections (e.g., forward connections, skip connections, recurrent connections). Furthermore, in various cases, any of such layers can be any suitable types of neural network layers having any suitable learnable or trainable internal parameters (e.g., any of such input layer, one or more hidden layers, or output layer can be convolutional layers, dense layers, batch normalization layers, LSTM layers, or transformer layers). Further still, in various cases, any of such layers can be any suitable types of neural network layers having any suitable fixed or non-trainable internal parameters (e.g., any of such input layer, one or more hidden layers, or output layer can be non-linearity layers, padding layers, pooling layers, or concatenation layers).

Regardless of the specific internal architecture (e.g., the specific numbers, types, or organizations of layers) that is implemented within the encoder portion 702, the encoder portion 702 can be configured to receive textual data (which can be accompanied by any suitable numerical or graphical data) and to produce embeddings based on such inputted textual data. In contrast, regardless of the specific internal architecture that is implemented within the synthesizer portion 704, the synthesizer portion 704 can be configured to receive embeddings produced by the encoder portion 702 and to produce synthesized textual content, synthesized numerical content, or synthesized graphical content based on such embeddings. As some non-limiting examples, the LLM 602 can be any of the following: ChatGPT; Gene.AI; Ollama; Bard; or Claude.

In any case, the localization component 320 can utilize the LLM 602 to electronically generate the set of outlier localizations 604. In particular, the localization component 320 can electronically execute the LLM 602 on both the scanned image 402 and the outlier identification text prompt 305. In various cases, such execution can cause the LLM 602 to produce the set of outlier localizations 604. More specifically, the localization component 320 can concatenate the scanned image 402 and the outlier identification text prompt 305 together. In various aspects, the localization component 320 can feed that concatenation to the input layer of the encoder portion 702. In various aspects, that concatenation can complete a forward pass through the one or more hidden layers of the encoder portion 702. In various instances, the output layer of the encoder portion 702 can compute or otherwise calculate one or more embeddings (not shown), based on activation maps or feature maps provided by the one or more hidden layers of the encoder portion 702. In various cases, those one or more embeddings can be routed to the input layer of the synthesizer portion 704. In various aspects, those one or more embeddings can complete a forward pass through the one or more hidden layers of the synthesizer portion 704. In various instances, the output layer of the synthesizer portion 704 can compute or otherwise calculate the set of outlier localizations 604 based on activation maps or feature maps provided by the one or more hidden layers of the synthesizer portion 704.

In any case, the set of outlier localizations 604 can be any suitable electronic data that indicate, convey, specify, or otherwise represent where (in the opinion of the LLM 602) respective instantiations of the specified structure of interest (e.g., indicated by the structure of interest definition 306) that exhibit the specified outlying characteristic (e.g., indicated by the outlying characteristic definition 308) are located within the scanned image 402 and thus within the specimen 304. More specifically, the set of outlier localizations 604 can comprise m localizations, for any suitable positive integer m: an outlier localization 604(1) to an outlier localization 604(m). In various aspects, each of the set of outlier localizations 604 can be one or more scalars, one or more vectors, one or more matrices, one or more tensors, or any suitable combination thereof that indicates or otherwise represents an intra-image location within the scanned image 402 of a visual object that meets or satisfies both the structure of interest definition 306 and the outlying characteristic definition 308. In some cases, each of the set of outlier localizations 604 can be a bounding box indicating a respective intra-image location. In other cases, each of the set of outlier localizations 604 can instead be a segmentation mask indicating a respective intra-image location. In even other cases, each of the set of outlier localizations 604 can be a pixel or voxel coordinate tuple indicating a respective intra-image location.

As a non-limiting example, suppose that the structure of interest definition 306 indicates a transistor drain and that the outlying characteristic definition 308 indicates a non-vertical orientation. In such example, the LLM 602 can be considered as determining that the scanned image 402 depicts or illustrates a first non-vertically oriented transistor drain, and the outlier localization 604(1) can be a first bounding box or a first segmentation mask that circumscribes or covers whichever pixels or voxels of the scanned image 402 that the LLM 602 has inferred or predicted belong to or make up that first non-vertically-oriented transistor drain. Alternatively, the outlier localization 604(1) can instead be a first coordinate tuple (e.g., x-coordinate, y-coordinate, or z-coordinate, as appropriate) that indicates where in the scanned image 402 one or more pixels or voxels are located that the LLM 602 has inferred or predicted belong to or make up that first non-vertically-oriented transistor drain. Likewise, the LLM 602 can be considered as determining that the scanned image 402 depicts or illustrates an m-th non-vertically oriented transistor drain, and the outlier localization 604(m) can be an m-th bounding box or an m-th segmentation mask that circumscribes or covers whichever pixels or voxels of the scanned image 402 that the LLM 602 has inferred or predicted belong to or make up that m-th non-vertically-oriented transistor drain. Alternatively, the outlier localization 604(m) can instead be an m-th coordinate tuple that indicates where in the scanned image 402 one or more pixels or voxels are located that the LLM 602 has inferred or predicted belong to or make up that m-th non-vertically-oriented transistor drain.

In other words, the outlier identification text prompt 305 can be considered as a semantic instruction to search the scanned image 402 for any illustrated objects that satisfy both the structure of interest definition 306 and the outlying characteristic definition 308, the LLM 602 can be considered as performing or conducting such search, and the set of outlier localizations 604 can be considered as the results obtained from such search. In still other words, the LLM 602 can be considered as performing a search through the pixels or voxels of the scanned image 402, which search is conditioned on or otherwise guided by the outlier identification text prompt 305, hence the term “text-conditioned.”

Note that, in various aspects, changing the semantic or substantive content of the outlier identification text prompt 305 can accordingly change the set of outlier localizations 604. Consider again the non-limiting example above where the structure of interest definition 306 indicates a transistor drain and where the outlying characteristic definition 308 indicates a non-vertical orientation. Now, suppose that the structure of interest definition 306 is changed to instead indicate a transistor fin rather than a transistor drain. In such situation, rather than localizing m distinct or respective non-vertically-oriented transistor drains in the scanned image 402, the LLM 602 can instead be considered as localizing m distinct or respective non-vertically-oriented transistor fins in the scanned image 402. In another instance, suppose that the structure of interest definition 306 still indicates a transistor drain but that the outlying characteristic definition 308 instead indicates a height of at least t nanometers, for any suitable positive real number t. In such situation, rather than localizing m distinct or respective non-vertically-oriented transistor drains in the scanned image 402, and rather than localizing m distinct or respective non-vertically-oriented transistor fins in the scanned image 402, the LLM 602 can instead be considered as localizing in the scanned image 402m distinct or respective transistor drains whose depicted heights are at least t nanometers.

Thus, the LLM 602 can be considered as localizing within the scanned image 402 whatever visual or visible objects that meet (in the opinion of the LLM 602) both the structure of interest definition 306 and the outlying characteristic definition 308. So, a user or technician can draft the outlier identification text prompt 305 so as to specify whatever structure of interest or outlying characteristic for which localization is desired, and the LLM 602 can localize accordingly. In this way, the LLM 602 can be considered as facilitating anomaly or outlying localization in charged-particle microscopy images in a more generalizable or flexible manner, as compared to existing techniques that do not leverage text-conditioning and thus where each respective localization model is rigidly restricted to localizing only a single type of structure of interest exhibiting a single type of outlying characteristic.

It should be understood that the LLM 602 can return more or fewer than m localizations, depending upon the substantive content of the outlier identification text prompt 305.

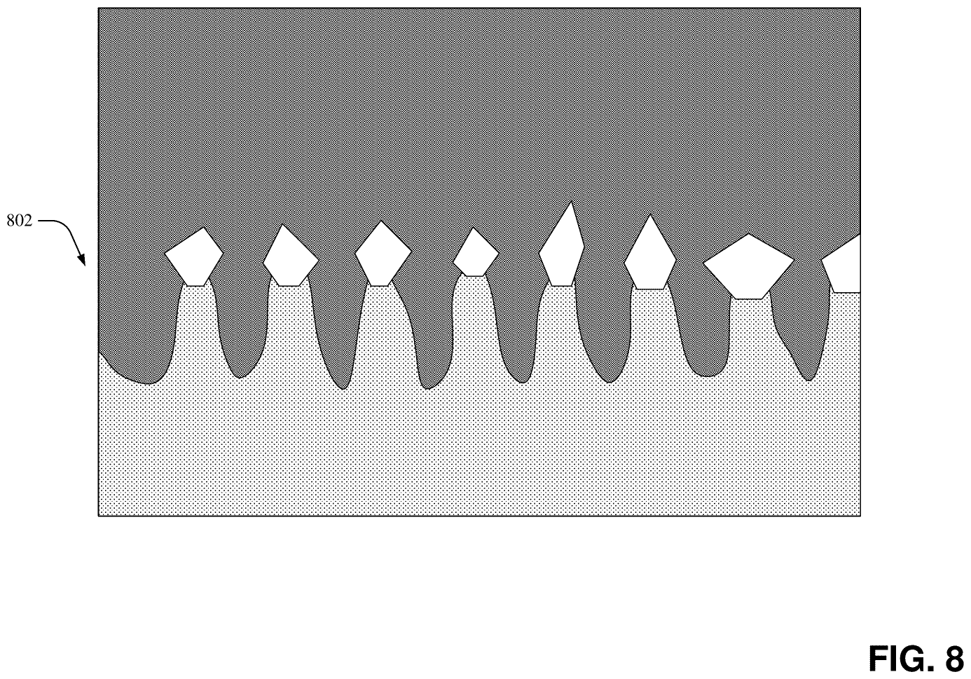

FIGS. 8-14 illustrate example, non-limiting dramatizations of localizations that were experimentally obtained by one or more embodiments described herein. In particular, the present inventors performed various real-world experiments with various embodiments described herein. However, such experiments involved proprietary scanned images which the present inventors are not at liberty to publish. Accordingly, such experiments are encapsulated by the dramatizations shown in FIGS. 8-14.

FIG. 8 illustrates a scanned image dramatization 802 depicting various microscopic or nanoscopic semiconductor structures. The present inventors reduced to practice an embodiment of the LLM 602 and leveraged that reduction-to-practice to localize various objects illustrated in a real-world scanned image that corresponds to the scanned image dramatization 802.

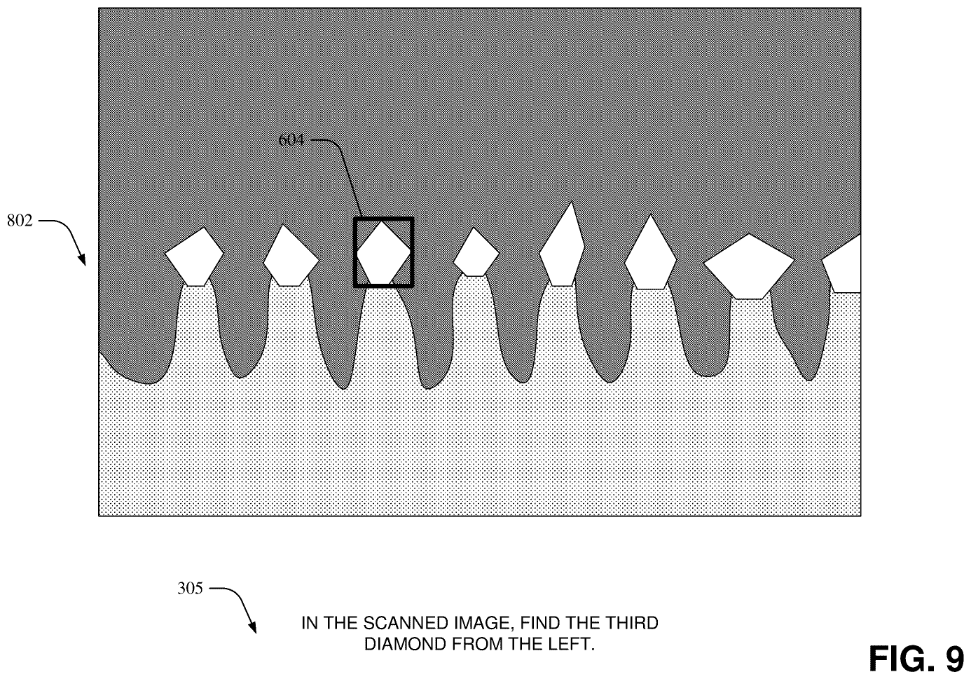

FIG. 9 illustrates a non-limiting example embodiment of the outlier identification text prompt 305. As shown in the non-limiting example of FIG. 9, the outlier identification text prompt 305 stated the following: “In the scanned image, find the third diamond from the left.” Here, the word “diamond” can be considered as the structure of interest definition 306, and phrase “third . . . from the left” can be considered as the outlying characteristic definition 308. The present inventors executed the reduced-to-practice version of the LLM 602 on both that version of the outlier identification text prompt 305 and the scanned image corresponding to the scanned image dramatization 802. As a result, the LLM produced as output (e.g., 604) a bounding box that circumscribed within that scanned image whatever visible diamond-shaped object that was positioned third when counting diamond-shaped objects from the left side of the image, as shown.

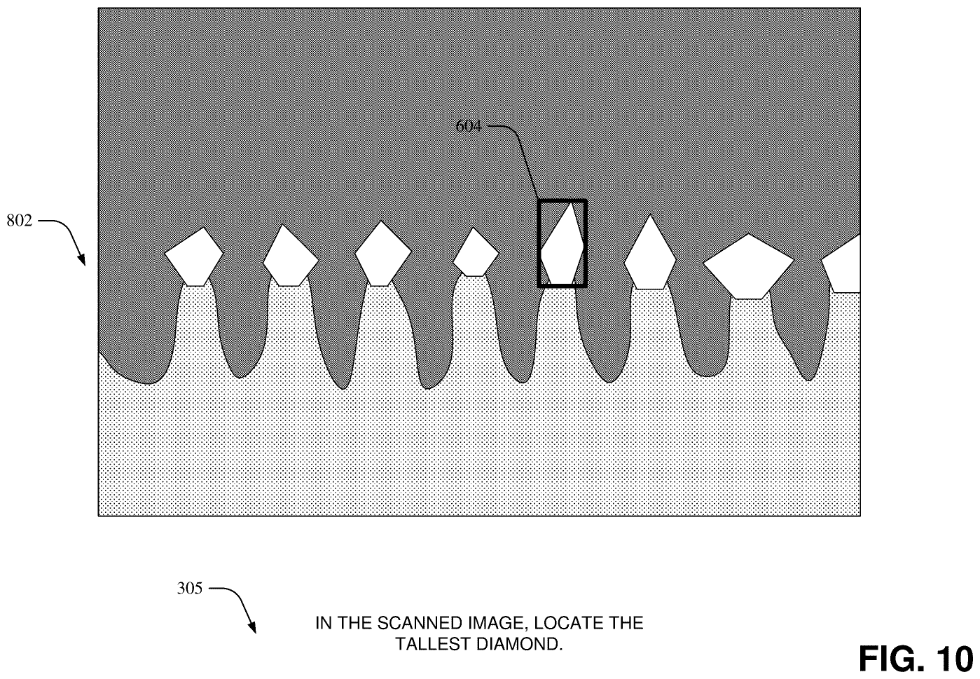

FIG. 10 illustrates another non-limiting example embodiment of the outlier identification text prompt 305. As shown in the non-limiting example of FIG. 10, the outlier identification text prompt 305 stated the following: “In the scanned image, locate the tallest diamond.” Here, the word “diamond” can be considered as the structure of interest definition 306, and word “tallest” can be considered as the outlying characteristic definition 308. The present inventors executed the reduced-to-practice version of the LLM 602 on both that version of the outlier identification text prompt 305 and the scanned image corresponding to the scanned image dramatization 802. As a result, the LLM produced as output (e.g., 604) a bounding box that circumscribed within that scanned image whatever visible diamond-shaped object that visually appeared to be tallest in the image, as shown.

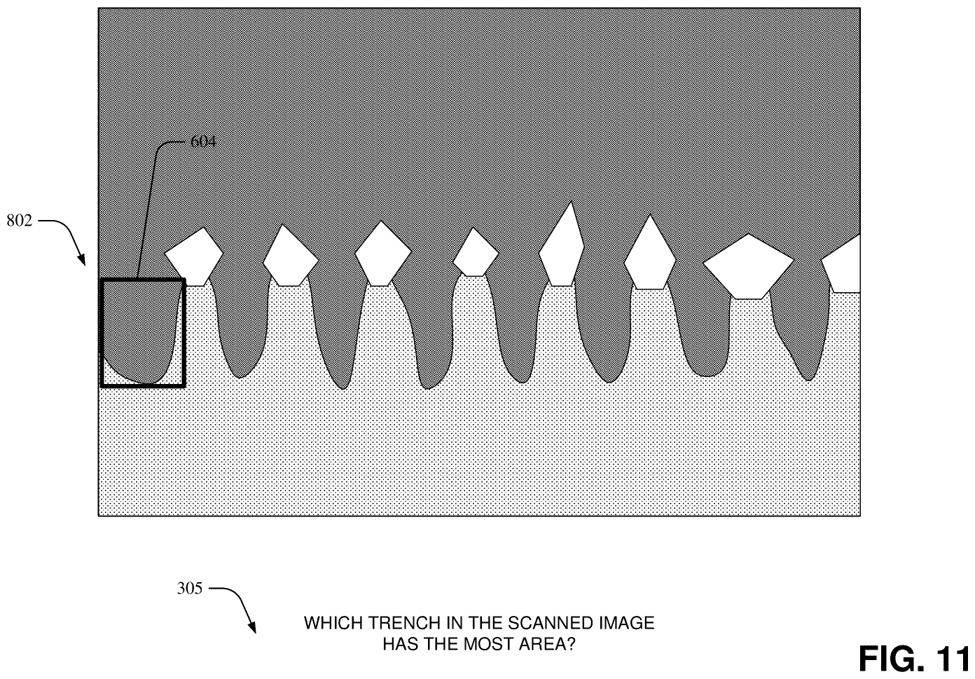

FIG. 11 illustrates a non-limiting example embodiment of the outlier identification text prompt 305. As shown in the non-limiting example of FIG. 11, the outlier identification text prompt 305 stated the following: “Which trench in the scanned image has the most area?” Here, the word “trench” can be considered as the structure of interest definition 306, and phrase “most area” can be considered as the outlying characteristic definition 308. The present inventors executed the reduced-to-practice version of the LLM 602 on both that version of the outlier identification text prompt 305 and the scanned image corresponding to the scanned image dramatization 802. As a result, the LLM produced as output (e.g., 604) a bounding box that circumscribed within that scanned image whatever visible object it recognized as a semiconductor trench that visually appeared to have the largest amount of spatial area, as shown.

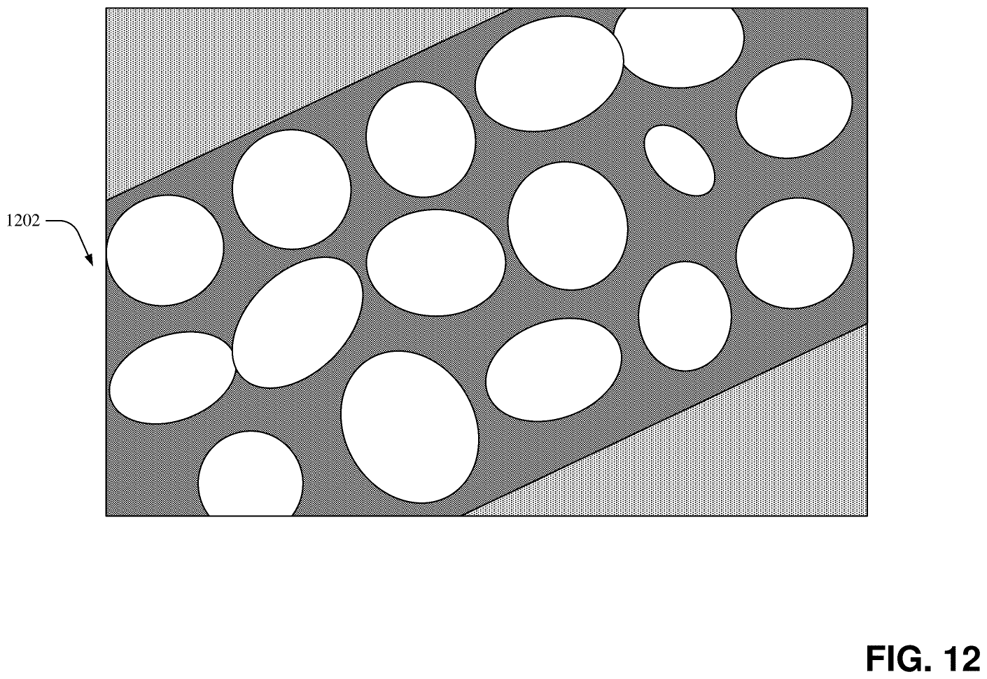

FIG. 12 illustrates a scanned image dramatization 1202 depicting various biological cellular structures. The present inventors utilized the above-mentioned reduced-to-practice version of the LLM 602 to localize various objects illustrated in a real-world scanned image that corresponds to the scanned image dramatization 1202.

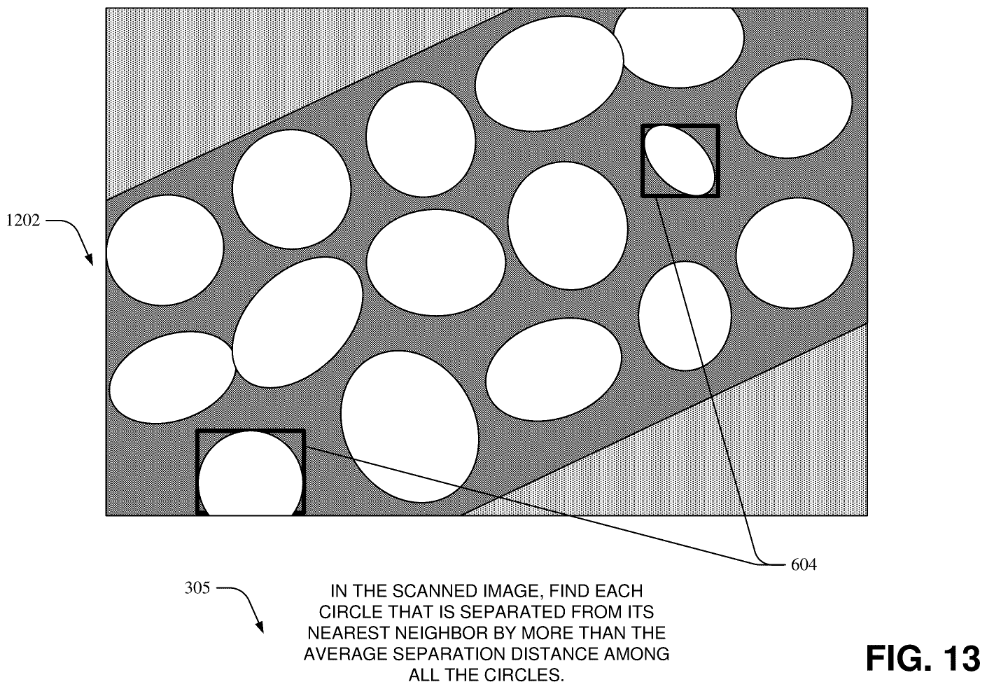

FIG. 13 illustrates a non-limiting example embodiment of the outlier identification text prompt 305. As shown in the non-limiting example of FIG. 13, the outlier identification text prompt 305 stated the following: “In the scanned image, find each circle that is separated from its nearest neighbor by more than the average separation distance among all the circles.” Here, the word “circle” can be considered as the structure of interest definition 306, and phrase “separated from its nearest neighbor by more than the average separation distance among all the circles” can be considered as the outlying characteristic definition 308. The present inventors executed the reduced-to-practice version of the LLM 602 on both that version of the outlier identification text prompt 305 and the scanned image corresponding to the scanned image dramatization 1202. As a result, the LLM produced as output (e.g., 604) multiple bounding boxes, each of which circumscribed within that scanned image whatever visible circular objects that visually appeared to be separated from their neighboring circular objects by more than the average circular object separation distance across the entire scanned image, as shown.

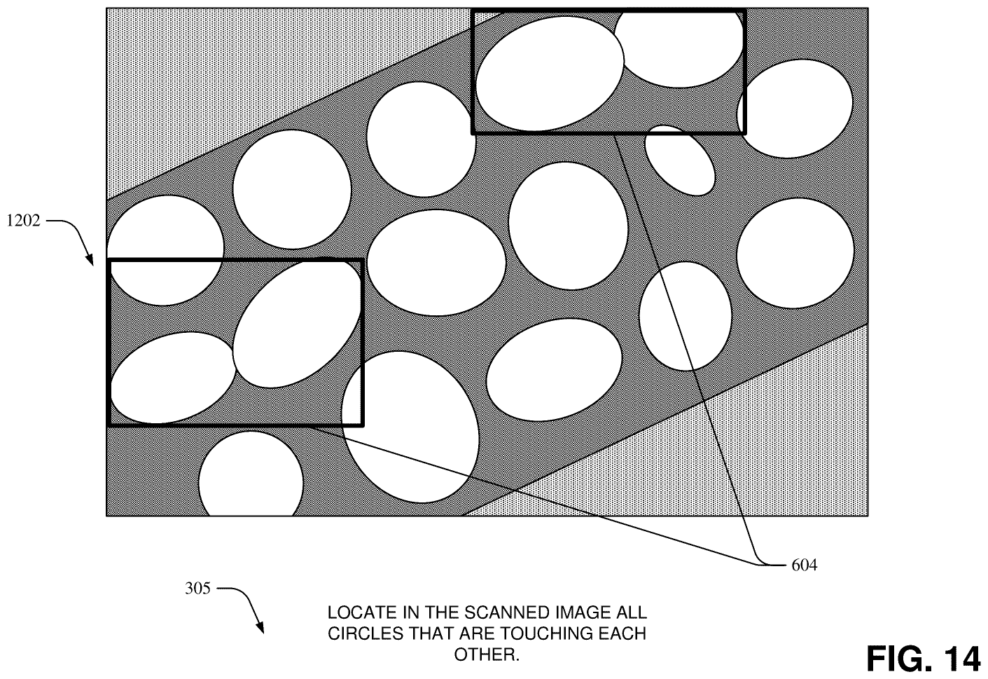

FIG. 14 illustrates another non-limiting example embodiment of the outlier identification text prompt 305. As shown in the non-limiting example of FIG. 14, the outlier identification text prompt 305 stated the following: “Locate in the scanned image all circles that are touching each other.” Here, the word “circles” can be considered as the structure of interest definition 306, and the phrase “touching each other” can be considered as the outlying characteristic definition 308. The present inventors executed the reduced-to-practice version of the LLM 602 on both that version of the outlier identification text prompt 305 and the scanned image corresponding to the scanned image dramatization 1202. As a result, the LLM produced as output (e.g., 604) multiple bounding boxes, each of which circumscribed within that scanned image whatever visible circular objects that visually appeared to be touching each other, as shown.

Note that the experiments conducted according to FIGS. 8-14 all involved the same reduced-to-practice version of the LLM 602. That is, the LLM 602 was not retrained or fine-tuned in the middle of such experiments. So, the non-limiting examples of FIGS. 8-14 help to demonstrate the immense generalizability and flexibility provided by various embodiments described herein. In other words, these experiments proved that a single LLM was able to provide accurate and reliable localization across various charged-particle microscopy images, across seemingly unrelated types of structures of interest, and across seemingly unrelated types of outlying characteristics. Contrast this with existing techniques that do not leverage text-conditioning and thus are far less flexible/generalizable.

In any case, the localization component 320 can electronically execute the LLM 602 on both the scanned image 402 and the outlier identification text prompt 305, thereby yielding the set of outlier localizations 604. In various embodiments, the localization component 320 can electronically inform a user or technician of the set of outlier localizations 604. As a non-limiting example, the localization component 320 can electronically transmit any of the set of outlier localizations 604 to any suitable computing device. As another non-limiting example, the localization component 320 can electronically render any of the set of outlier localizations 604 on any suitable electronic display (e.g., on a display or screen of the charged-particle microscope 302 or of an associated computerized workstation).

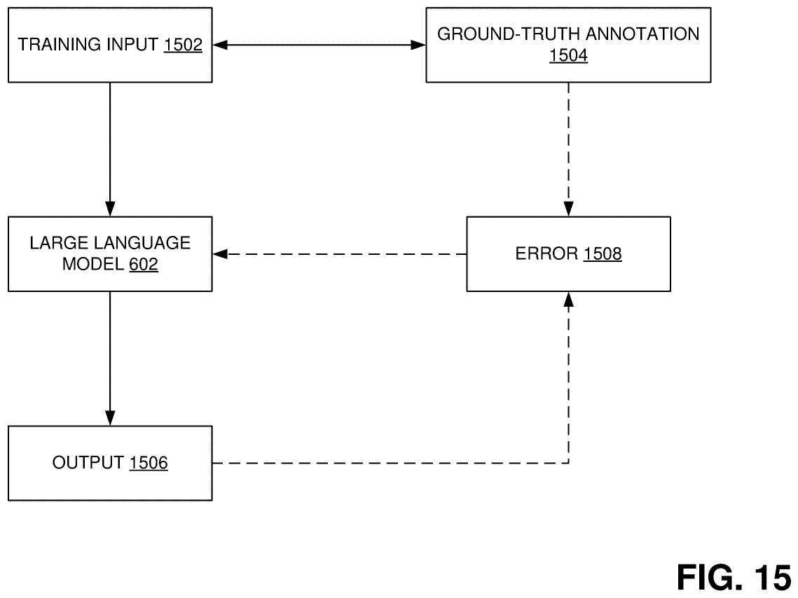

In order for the set of outlier localizations 604 to be accurate or correct in accordance with various embodiments described herein, the LLM 602 can first undergo training. A non-limiting example of such training is described with respect to FIG. 15.

FIG. 15 illustrates an example, non-limiting block diagram showing how the LLM 602 can be trained in accordance with one or more embodiments described herein.

In various aspects, prior to beginning training, the trainable internal parameters (e.g., convolutional kernels, weight matrices, bias values) of the LLM 602 can be initialized in any suitable fashion (e.g., via random initialization) by the system 310.

In various embodiments, there can be a training input 1502 and a ground-truth annotation 1504. In various aspects, the training input 1502 can be any suitable textual, numerical, or graphical data that can be received by the LLM 602 as described herein. As a non-limiting example, the training input 1502 can be a concatenation of: a training scanned image produced by a charged-particle microscope (e.g., can have the same format, size, or dimensionality as the scanned image 402); and a training outlier identification text prompt provided by a user or technician (e.g., can have the same format, size, or dimensionality as the outlier identification text prompt 305). In various instances, the ground-truth annotation 1504 can be whatever correct or accurate outlier localizations (e.g., correct or accurate bounding boxes, correct or accurate segmentation masks, correct or accurate coordinate tuples) that is known or deemed to correspond to the training input 1502 (e.g., can have same format, size, or dimensionality as the set of outlier localizations 604).

In any case, the system 310 can cause the LLM 602 to be executed on the training input 1502, thereby causing the LLM 602 to produce an output 1506. More specifically, in some cases, the training input 1502 can be fed or routed to the input layer of the LLM 602, the training input 1502 can complete a forward pass through the one or more hidden layers of the LLM 602, and the output layer of the LLM 602 can compute the output 1506 based on activation maps or feature maps provided by the one or more hidden layers of the LLM 602.

Note that the format, size, or dimensionality of the output 1506 can be dictated by the number, arrangement, sizes, or other characteristics of the neurons, convolutional kernels, attention blocks, or other internal parameters of the output layer (or of any other layers) of the LLM 602. Accordingly, the output 1506 can be forced to have any desired format, size, or dimensionality, by adding, removing, or otherwise adjusting characteristics of the output layer (or of any other layers) of the LLM 602.

In various aspects, the output 1506 can be considered as the predicted or inferred outlier localizations (e.g., predicted or inferred bounding boxes, predicted or inferred segmentation masks, predicted or inferred pixel or voxel coordinate tuples) that the LLM 602 has synthesized based on the training input 1502. Note that, if the LLM 602 has so far undergone no or little training, then the output 1506 can be highly inaccurate. In other words, the output 1506 can be very different from the ground-truth annotation 1504.

In various aspects, an error 1508 (e.g., mean absolute error, mean squared error, cross-entropy error) between the output 1506 and the ground-truth annotation 1504 can be computed by the system 310. In various instances, the trainable internal parameters of the LLM 602 can be incrementally updated via backpropagation (e.g., stochastic gradient descent) based on the error 1508.

In various cases, such execution-and-update procedure can be repeated for any suitable number input-annotation pairs. This can ultimately cause the trainable internal parameters of the LLM 602 to become iteratively optimized for accurately performing outlier localizations based on inputted and text-conditioned scanned images. In various aspects, any suitable training batch sizes, any suitable error/loss functions, or any suitable training termination criteria can be utilized during such training.

Although the herein disclosure mainly describes the LLM 602 as being trained in supervised fashion, this is a mere non-limiting example for ease of explanation and illustration. In various embodiments, any other suitable training paradigms can be used to train the LLM 602, such as unsupervised training or reinforcement learning, any of which may be federated or unfederated.

Although the herein disclosure mainly describes the localization component 320 as rendering or presenting the set of outlier localizations 604 to the user or technician of the charged-particle microscope 302, these are mere non-limiting examples for ease of explanation and illustration. In various embodiments, the localization component 320 can electronically transmit the set of outlier localizations 604 to any suitable computing device that is associated with the charged-particle microscope. As a non-limiting example, the localization component 320 can share the set of outlier localizations 604 with any suitable downstream software tools or applications that operate for or in conjunction with the charged-particle microscope 302 (e.g., some embodiments can involve sending the set of outlier localizations 604 to such downstream software tools or applications rather than presenting them to the user or technician).

Although the herein disclosure mainly describes the LLM 602 as receiving natural language inputs (e.g., 305) provided by the user or technician of the charged-particle microscope 302, these are mere non-limiting examples for ease of explanation and illustration. In various embodiments, the LLM 602 can receive natural language inputs that are synthesized by any suitable upstream generative models (e.g., in some cases, the outlier identification text prompt 305 can be synthesized by an upstream generative artificial intelligence model rather than being provided manually by the user or technician).

In various instances, machine learning algorithms or models can be implemented in any suitable way to facilitate any suitable aspects described herein. To facilitate some of the above-described machine learning aspects of various embodiments, consider the following discussion of artificial intelligence (AI). Various embodiments described herein can employ artificial intelligence to facilitate automating one or more features or functionalities. The components can employ various AI-based schemes for carrying out various embodiments/examples disclosed herein. In order to provide for or aid in the numerous determinations (e.g., determine, ascertain, infer, calculate, predict, prognose, estimate, derive, forecast, detect, compute) described herein, components described herein can examine the entirety or a subset of the data to which it is granted access and can provide for reasoning about or determine states of the system or environment from a set of observations as captured via events or data. Determinations can be employed to identify a specific context or action, or can generate a probability distribution over states, for example. The determinations can be probabilistic; that is, the computation of a probability distribution over states of interest based on a consideration of data and events. Determinations can also refer to techniques employed for composing higher-level events from a set of events or data.

Such determinations can result in the construction of new events or actions from a set of observed events or stored event data, whether or not the events are correlated in close temporal proximity, and whether the events and data come from one or several event and data sources. Components disclosed herein can employ various classification (explicitly trained (e.g., via training data) as well as implicitly trained (e.g., via observing behavior, preferences, historical information, receiving extrinsic information, and so on)) schemes or systems (e.g., support vector machines, neural networks, expert systems, Bayesian belief networks, fuzzy logic, data fusion engines, and so on) in connection with performing automatic or determined action in connection with the claimed subject matter. Thus, classification schemes or systems can be used to automatically learn and perform a number of functions, actions, or determinations.

A classifier can map an input attribute vector, z=(z₁, z₂, z₃, z₄, zₙ), to a confidence that the input belongs to a class, as by f(z)=confidence(class). Such classification can employ a probabilistic or statistical-based analysis (e.g., factoring into the analysis utilities and costs) to determinate an action to be automatically performed. A support vector machine (SVM) can be an example of a classifier that can be employed. The SVM operates by finding a hyper-surface in the space of possible inputs, where the hyper-surface attempts to split the triggering criteria from the non-triggering events. Intuitively, this makes the classification correct for testing data that is near, but not identical to training data. Other directed and undirected model classification approaches include, e.g., naïve Bayes, Bayesian networks, decision trees, neural networks, fuzzy logic models, or probabilistic classification models providing different patterns of independence, any of which can be employed. Classification as used herein also is inclusive of statistical regression that is utilized to develop models of priority.

In order to provide additional context for various embodiments described herein, FIG. 16 and the following discussion are intended to provide a brief, general description of a suitable computing environment 1600 in which the various embodiments of the embodiment described herein can be implemented. While the embodiments have been described above in the general context of computer-executable instructions that can run on one or more computers, those skilled in the art will recognize that the embodiments can be also implemented in combination with other program modules or as a combination of hardware and software.

Generally, program modules include routines, programs, components, data structures, etc., that perform particular tasks or implement particular abstract data types. Moreover, those skilled in the art will appreciate that the inventive methods can be practiced with other computer system configurations, including single-processor or multi-processor computer systems, minicomputers, mainframe computers, Internet of Things (IoT) devices, distributed computing systems, as well as personal computers, hand-held computing devices, microprocessor-based or programmable consumer electronics, and the like, each of which can be operatively coupled to one or more associated devices.

The illustrated embodiments of the embodiments herein can be also practiced in distributed computing environments where certain tasks are performed by remote processing devices that are linked through a communications network. In a distributed computing environment, program modules can be located in both local and remote memory storage devices.

Computing devices typically include a variety of media, which can include computer-readable storage media, machine-readable storage media, or communications media, which two terms are used herein differently from one another as follows. Computer-readable storage media or machine-readable storage media can be any available storage media that can be accessed by the computer and includes both volatile and nonvolatile media, removable and non-removable media. By way of example, and not limitation, computer-readable storage media or machine-readable storage media can be implemented in connection with any method or technology for storage of information such as computer-readable or machine-readable instructions, program modules, structured data or unstructured data.

Computer-readable storage media can include, but are not limited to, random access memory (RAM), read only memory (ROM), electrically erasable programmable read only memory (EEPROM), flash memory or other memory technology, compact disk read only memory (CD-ROM), digital versatile disk (DVD), Blu-ray disc (BD) or other optical disk storage, magnetic cassettes, magnetic tape, magnetic disk storage or other magnetic storage devices, solid state drives or other solid state storage devices, or other tangible or non-transitory media which can be used to store desired information. In this regard, the terms “tangible” or “non-transitory” herein as applied to storage, memory or computer-readable media, are to be understood to exclude only propagating transitory signals per se as modifiers and do not relinquish rights to all standard storage, memory or computer-readable media that are not only propagating transitory signals per se.

Computer-readable storage media can be accessed by one or more local or remote computing devices, e.g., via access requests, queries or other data retrieval protocols, for a variety of operations with respect to the information stored by the medium.

Communications media typically embody computer-readable instructions, data structures, program modules or other structured or unstructured data in a data signal such as a modulated data signal, e.g., a carrier wave or other transport mechanism, and includes any information delivery or transport media. The term “modulated data signal” or signals refers to a signal that has one or more of its characteristics set or changed in such a manner as to encode information in one or more signals. By way of example, and not limitation, communication media include wired media, such as a wired network or direct-wired connection, and wireless media such as acoustic, RF, infrared and other wireless media.

With reference again to FIG. 16, the example environment 1600 for implementing various embodiments of the aspects described herein includes a computer 1602, the computer 1602 including a processing unit 1604, a system memory 1606 and a system bus 1608. The system bus 1608 couples system components including, but not limited to, the system memory 1606 to the processing unit 1604. The processing unit 1604 can be any of various commercially available processors. Dual microprocessors and other multi-processor architectures can also be employed as the processing unit 1604.

The system bus 1608 can be any of several types of bus structure that can further interconnect to a memory bus (with or without a memory controller), a peripheral bus, and a local bus using any of a variety of commercially available bus architectures. The system memory 1606 includes ROM 1610 and RAM 1612. A basic input/output system (BIOS) can be stored in a non-volatile memory such as ROM, erasable programmable read only memory (EPROM), EEPROM, which BIOS contains the basic routines that help to transfer information between elements within the computer 1602, such as during startup. The RAM 1612 can also include a high-speed RAM such as static RAM for caching data.

The computer 1602 further includes an internal hard disk drive (HDD) 1614 (e.g., EIDE, SATA), one or more external storage devices 1616 (e.g., a magnetic floppy disk drive (FDD) 1616, a memory stick or flash drive reader, a memory card reader, etc.) and a drive 1620, e.g., such as a solid state drive, an optical disk drive, which can read or write from a disk 1622, such as a CD-ROM disc, a DVD, a BD, etc. Alternatively, where a solid state drive is involved, disk 1622 would not be included, unless separate. While the internal HDD 1614 is illustrated as located within the computer 1602, the internal HDD 1614 can also be configured for external use in a suitable chassis (not shown). Additionally, while not shown in environment 1600, a solid state drive (SSD) could be used in addition to, or in place of, an HDD 1614. The HDD 1614, external storage device(s) 1616 and drive 1620 can be connected to the system bus 1608 by an HDD interface 1624, an external storage interface 1626 and a drive interface 1628, respectively. The interface 1624 for external drive implementations can include at least one or both of Universal Serial Bus (USB) and Institute of Electrical and Electronics Engineers (IEEE) 1394 interface technologies. Other external drive connection technologies are within contemplation of the embodiments described herein.

The drives and their associated computer-readable storage media provide nonvolatile storage of data, data structures, computer-executable instructions, and so forth. For the computer 1602, the drives and storage media accommodate the storage of any data in a suitable digital format. Although the description of computer-readable storage media above refers to respective types of storage devices, it should be appreciated by those skilled in the art that other types of storage media which are readable by a computer, whether presently existing or developed in the future, could also be used in the example operating environment, and further, that any such storage media can contain computer-executable instructions for performing the methods described herein.

A number of program modules can be stored in the drives and RAM 1612, including an operating system 1630, one or more application programs 1632, other program modules 1634 and program data 1636. All or portions of the operating system, applications, modules, or data can also be cached in the RAM 1612. The systems and methods described herein can be implemented utilizing various commercially available operating systems or combinations of operating systems.

Computer 1602 can optionally comprise emulation technologies. For example, a hypervisor (not shown) or other intermediary can emulate a hardware environment for operating system 1630, and the emulated hardware can optionally be different from the hardware illustrated in FIG. 16. In such an embodiment, operating system 1630 can comprise one virtual machine (VM) of multiple VMs hosted at computer 1602. Furthermore, operating system 1630 can provide runtime environments, such as the Java runtime environment or the .NET framework, for applications 1632. Runtime environments are consistent execution environments that allow applications 1632 to run on any operating system that includes the runtime environment. Similarly, operating system 1630 can support containers, and applications 1632 can be in the form of containers, which are lightweight, standalone, executable packages of software that include, e.g., code, runtime, system tools, system libraries and settings for an application.

Further, computer 1602 can be enable with a security module, such as a trusted processing module (TPM). For instance with a TPM, boot components hash next in time boot components, and wait for a match of results to secured values, before loading a next boot component. This process can take place at any layer in the code execution stack of computer 1602, e.g., applied at the application execution level or at the operating system (OS) kernel level, thereby enabling security at any level of code execution.

A user can enter commands and information into the computer 1602 through one or more wired/wireless input devices, e.g., a keyboard 1638, a touch screen 1640, and a pointing device, such as a mouse 1642. Other input devices (not shown) can include a microphone, an infrared (IR) remote control, a radio frequency (RF) remote control, or other remote control, a joystick, a virtual reality controller or virtual reality headset, a game pad, a stylus pen, an image input device, e.g., camera(s), a gesture sensor input device, a vision movement sensor input device, an emotion or facial detection device, a biometric input device, e.g., fingerprint or iris scanner, or the like. These and other input devices are often connected to the processing unit 1604 through an input device interface 1644 that can be coupled to the system bus 1608, but can be connected by other interfaces, such as a parallel port, an IEEE 1394 serial port, a game port, a USB port, an IR interface, a BLUETOOTH® interface, etc.

A monitor 1646 or other type of display device can be also connected to the system bus 1608 via an interface, such as a video adapter 1648. In addition to the monitor 1646, a computer typically includes other peripheral output devices (not shown), such as speakers, printers, etc.

The computer 1602 can operate in a networked environment using logical connections via wired or wireless communications to one or more remote computers, such as a remote computer(s) 1650. The remote computer(s) 1650 can be a workstation, a server computer, a router, a personal computer, portable computer, microprocessor-based entertainment appliance, a peer device or other common network node, and typically includes many or all of the elements described relative to the computer 1602, although, for purposes of brevity, only a memory/storage device 1652 is illustrated. The logical connections depicted include wired/wireless connectivity to a local area network (LAN) 1654 or larger networks, e.g., a wide area network (WAN) 1656. Such LAN and WAN networking environments are commonplace in offices and companies, and facilitate enterprise-wide computer networks, such as intranets, all of which can connect to a global communications network, e.g., the Internet.

When used in a LAN networking environment, the computer 1602 can be connected to the local network 1654 through a wired or wireless communication network interface or adapter 1658. The adapter 1658 can facilitate wired or wireless communication to the LAN 1654, which can also include a wireless access point (AP) disposed thereon for communicating with the adapter 1658 in a wireless mode.

When used in a WAN networking environment, the computer 1602 can include a modem 1660 or can be connected to a communications server on the WAN 1656 via other means for establishing communications over the WAN 1656, such as by way of the Internet. The modem 1660, which can be internal or external and a wired or wireless device, can be connected to the system bus 1608 via the input device interface 1644. In a networked environment, program modules depicted relative to the computer 1602 or portions thereof, can be stored in the remote memory/storage device 1652. It will be appreciated that the network connections shown are example and other means of establishing a communications link between the computers can be used.

When used in either a LAN or WAN networking environment, the computer 1602 can access cloud storage systems or other network-based storage systems in addition to, or in place of, external storage devices 1616 as described above, such as but not limited to a network virtual machine providing one or more aspects of storage or processing of information. Generally, a connection between the computer 1602 and a cloud storage system can be established over a LAN 1654 or WAN 1656 e.g., by the adapter 1658 or modem 1660, respectively. Upon connecting the computer 1602 to an associated cloud storage system, the external storage interface 1626 can, with the aid of the adapter 1658 or modem 1660, manage storage provided by the cloud storage system as it would other types of external storage. For instance, the external storage interface 1626 can be configured to provide access to cloud storage sources as if those sources were physically connected to the computer 1602.

The computer 1602 can be operable to communicate with any wireless devices or entities operatively disposed in wireless communication, e.g., a printer, scanner, desktop or portable computer, portable data assistant, communications satellite, any piece of equipment or location associated with a wirelessly detectable tag (e.g., a kiosk, news stand, store shelf, etc.), and telephone. This can include Wireless Fidelity (Wi-Fi) and BLUETOOTH® wireless technologies. Thus, the communication can be a predefined structure as with a conventional network or simply an ad hoc communication between at least two devices.

FIG. 17 is a schematic block diagram of a sample computing environment 1700 with which the disclosed subject matter can interact. The sample computing environment 1700 includes one or more client(s) 1710. The client(s) 1710 can be hardware or software (e.g., threads, processes, computing devices). The sample computing environment 1700 also includes one or more server(s) 1730. The server(s) 1730 can also be hardware or software (e.g., threads, processes, computing devices). The servers 1730 can house threads to perform transformations by employing one or more embodiments as described herein, for example. One possible communication between a client 1710 and a server 1730 can be in the form of a data packet adapted to be transmitted between two or more computer processes. The sample computing environment 1700 includes a communication framework 1750 that can be employed to facilitate communications between the client(s) 1710 and the server(s) 1730. The client(s) 1710 are operably connected to one or more client data store(s) 1720 that can be employed to store information local to the client(s) 1710. Similarly, the server(s) 1730 are operably connected to one or more server data store(s) 1740 that can be employed to store information local to the servers 1730.

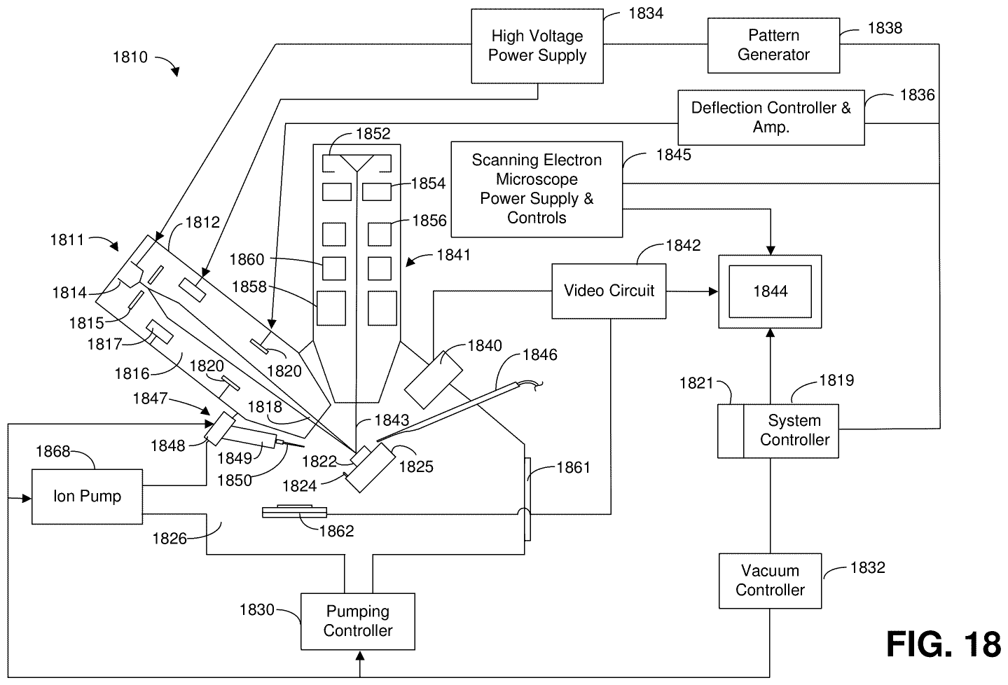

An example, non-limiting apparatus for performing various embodiments described herein is shown in FIG. 18. FIG. 18 illustrates a non-limiting example of a dual beam system 1810 with a vertically mounted scanning electron microscope (SEM) column and a focused ion beam (FIB) column mounted at an angle of approximately 52 degrees from the vertical. Such dual beam systems are commercially available, for example, from FEI Company, Hillsboro, Oregon, the assignee of the present application. While FIG. 18 shows an example of suitable microscopy hardware with which various embodiments described herein can be implemented, it is to be appreciated that such microscopy hardware is non-limiting. In other words, various embodiments described herein can be implemented in conjunction with any other suitable types of microscopy hardware. The dual beam system 1810 is a non-limiting example of the charged-particle microscope 302 or of any other scientific instruments discussed above.

A scanning electron microscope 1841, along with a power supply and control unit 1845, can be provided with the dual beam system 1810. An electron beam 1843 can be emitted from a cathode 1852 by applying voltage between the cathode 1852 and an anode 1854. The electron beam 1843 can be focused to a fine spot by means of a condensing lens 1856 and an objective lens 1858. The electron beam 1843 can be scanned two-dimensionally on any suitable specimen by means of a deflection coil 1860. Operation of the condensing lens 1856, the objective lens 1858, or the deflection coil 1860 can be controlled by the power supply and control unit 1845.

The electron beam 1843 can be focused onto a substrate 1822, which can be on a movable X-Y stage 1825 within a lower chamber 1826. When the electrons in the electron beam 1843 strike the substrate 1822, secondary electrons can be emitted. These secondary electrons can be detected by a secondary electron detector 1840 as discussed below. A scanning transmission electron microscopy (STEM) detector 1862, located beneath a transmission electron microscopy (TEM) sample holder 1824 and the movable X-Y stage 1825, can collect electrons that are transmitted through the sample mounted on the TEM sample holder 1824 as discussed above.

The dual beam system 1810 can also include a focused ion beam (FIB) system 1811 which can comprise an evacuated chamber having an upper neck portion 1812 within which can be located an ion source 1814 and a focusing column 1816 including extractor electrodes and an electrostatic optical system. The axis of the focusing column 1816 can be tilted 52 degrees (or any other suitable angular displacement) from the axis of the electron column. The ion column 1812 can include an ion source 1814, an extraction electrode 1815, a focusing element 1817, deflection elements 1820, and a focused ion beam 1818. The focused ion beam 1818 can pass from the ion source 1814 through the focusing column 1816 and between electrostatic deflection means schematically indicated at numeral 1820 toward the substrate 1822, which can comprise, for example, a semiconductor device positioned on the movable X-Y stage 1825 within the lower chamber 1826.

The movable X-Y stage 1825 can move in a horizontal plane (along X and Y axes) and vertically (along Z axis). The movable X-Y stage 1825 can tilt approximately sixty (60) degrees and rotate about the Z axis. In some embodiments, a separate TEM sample stage (not shown) can be used. Such a TEM sample stage can be moveable in the X, Y, and Z axes. A door 1861 can be opened for inserting the substrate 1822 onto the movable X-Y stage 1825 or also for servicing an internal gas supply reservoir, if one is used. The door 1861 can be interlocked so that it cannot be opened if the system is under vacuum.

An ion pump 1868 can be employed for evacuating the neck portion 1812. The chamber 1826 can be evacuated with a turbomolecular and mechanical pumping system 1830 under the control of a vacuum controller 1832. Such vacuum system can provide within the chamber 1826 a vacuum of between approximately 1×10⁻⁷ Torr and 5×10⁻⁴ Torr. If an etch assisting, an etch retarding gas, or a deposition precursor gas is used, the chamber background pressure may rise, typically to about 1×10⁻⁵ Torr.

A high voltage power supply 1834 can provide an appropriate acceleration voltage to electrodes in the focusing column 1816 for energizing and the focused ion beam 1818. When it strikes the substrate 1822, material can be sputtered (that is, physically ejected) from the sample. Alternatively, the focused ion beam 1818 can decompose a precursor gas to deposit a material.

The high voltage power supply 1834 can be connected to the ion source 1814 (which can be a liquid metal ion source) as well as to appropriate electrodes in the ion beam focusing column 1816 for forming an approximately 1 keV to 60 keV ion beam 1818 and directing the same toward a sample. A deflection controller and amplifier 1836, operated in accordance with a prescribed pattern provided by a pattern generator 1838, can be coupled to the deflection elements 1820 (which can be deflection plates) whereby the focused ion beam 1818 may be controlled manually or automatically to trace out a corresponding pattern on the upper surface of the substrate 1822. In some systems, the deflection elements 1820 can be placed before the final lens. Beam blanking electrodes (not shown) within the ion beam focusing column 1816 can cause the focused ion beam 1818 to impact onto a blanking aperture (not shown) instead of the substrate 1822 when a blanking controller (not shown) applies a blanking voltage to a blanking electrode.

The ion source 1814 can provide a metal ion beam of gallium, for example. In other examples, the ion source 1814 may be a plasma ion source that extracts ions from a generated plasma. The source can be capable of being focused into a sub one-tenth micrometer wide beam at the substrate 1822 for either modifying the substrate 1822 by ion milling, enhanced etch, material deposition, or for the purpose of imaging the substrate 1822.

A charged particle detector 1840, such as an Everhart Thornley or multi-channel plate, used for detecting secondary ion or electron emission can be connected to a video circuit 1842 that can supply drive signals to a video monitor 1844 and receive deflection signals from a system controller 1819. The location of the charged particle detector 1840 within the lower chamber 1826 can vary in different embodiments. For example, the charged particle detector 1840 can be coaxial with the ion beam and include a hole for allowing the ion beam to pass. In other embodiments, secondary particles can be collected through a final lens and then diverted off axis for collection.

A micromanipulator 1847 can precisely move objects within the vacuum chamber. The micromanipulator 1847 may comprise precision electric motors 1848 positioned outside the vacuum chamber to provide X, Y, Z, and theta control of a portion 1849 positioned within the vacuum chamber. The micromanipulator 1847 can be fitted with different end effectors for manipulating small objects. In various embodiments described herein, the end effector can be a thin probe 1850.

A gas delivery system 1846 can extend into the lower chamber 1826 for introducing and directing a gaseous vapor toward the substrate 1822. U.S. Pat. No. 5,851,413 to Casella et al. for “Gas Delivery Systems for Particle Beam Processing,” assigned to the assignee of the present invention, describes a suitable gas delivery system 1846. Another gas delivery system is described in U.S. Pat. No. 5,435,850 to Rasmussen for a “Gas Injection System,” also assigned to the assignee of the present invention. For example, iodine can be delivered to enhance etching, or a metal organic compound can be delivered to deposit a metal.

The system controller 1819 can control the operations of the various parts of the dual beam system 1810. Through the system controller 1819, a user can cause the focused ion beam 1818 or the electron beam 1843 to be scanned in a desired manner through commands entered into any suitable user interface (not shown).

Alternatively, the system controller 1819 may control the dual beam system 1810 in accordance with programmed instructions stored in a memory 1821. In various embodiments, any of the one or more software components 315 (e.g., the access component 316, the scan component 318, the localization component 320) can be implemented in or otherwise executed by the system controller 1819.

Various embodiments may be a system, a method, an apparatus or a computer program product at any possible technical detail level of integration. The computer program product can include a computer readable storage medium (or media) having computer readable program instructions thereon for causing a processor to carry out aspects of various embodiments. The computer readable storage medium can be a tangible device that can retain and store instructions for use by an instruction execution device. The computer readable storage medium can be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium can also include the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network or a wireless network. The network can comprise copper transmission cables, optical transmission fibers, wireless transmission, routers, firewalls, switches, gateway computers or edge servers. A network adapter card or network interface in each computing/processing device receives computer readable program instructions from the network and forwards the computer readable program instructions for storage in a computer readable storage medium within the respective computing/processing device. Computer readable program instructions for carrying out operations of various embodiments can be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions can execute entirely on the user's computer, partly on the user's computer, as a stand-alone software package, partly on the user's computer and partly on a remote computer or entirely on the remote computer or server. In the latter scenario, the remote computer can be connected to the user's computer through any type of network, including a local area network (LAN) or a wide area network (WAN), or the connection can be made to an external computer (for example, through the Internet using an Internet Service Provider). In some embodiments, electronic circuitry including, for example, programmable logic circuitry, field-programmable gate arrays (FPGA), or programmable logic arrays (PLA) can execute the computer readable program instructions by utilizing state information of the computer readable program instructions to personalize the electronic circuitry, in order to perform various aspects.

Various aspects are described herein with reference to flowchart illustrations or block diagrams of methods, apparatus (systems), and computer program products according to various embodiments. It will be understood that each block of the flowchart illustrations or block diagrams, and combinations of blocks in the flowchart illustrations or block diagrams, can be implemented by computer readable program instructions. These computer readable program instructions can be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart or block diagram block or blocks. These computer readable program instructions can also be stored in a computer readable storage medium that can direct a computer, a programmable data processing apparatus, or other devices to function in a particular manner, such that the computer readable storage medium having instructions stored therein comprises an article of manufacture including instructions which implement aspects of the function/act specified in the flowchart or block diagram block or blocks. The computer readable program instructions can also be loaded onto a computer, other programmable data processing apparatus, or other device to cause a series of operational acts to be performed on the computer, other programmable apparatus or other device to produce a computer implemented process, such that the instructions which execute on the computer, other programmable apparatus, or other device implement the functions/acts specified in the flowchart or block diagram block or blocks.

The flowcharts and block diagrams in the Figures illustrate the architecture, functionality, and operation of possible implementations of systems, methods, and computer program products according to various embodiments. In this regard, each block in the flowchart or block diagrams can represent a module, segment, or portion of instructions, which comprises one or more executable instructions for implementing the specified logical function(s). In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved. It will also be noted that each block of the block diagrams or flowchart illustration, and combinations of blocks in the block diagrams or flowchart illustration, can be implemented by special purpose hardware-based systems that perform the specified functions or acts or carry out combinations of special purpose hardware and computer instructions.

While the subject matter has been described above in the general context of computer-executable instructions of a computer program product that runs on a computer or computers, those skilled in the art will recognize that this disclosure also can or can be implemented in combination with other program modules. Generally, program modules include routines, programs, components, data structures, etc. that perform particular tasks or implement particular abstract data types. Moreover, those skilled in the art will appreciate that various aspects can be practiced with other computer system configurations, including single-processor or multiprocessor computer systems, mini-computing devices, mainframe computers, as well as computers, hand-held computing devices (e.g., PDA, phone), microprocessor-based or programmable consumer or industrial electronics, and the like. The illustrated aspects can also be practiced in distributed computing environments in which tasks are performed by remote processing devices that are linked through a communications network. However, some, if not all aspects of this disclosure can be practiced on stand-alone computers. In a distributed computing environment, program modules can be located in both local and remote memory storage devices.

As used in this application, the terms “component,” “system,” “platform,” “interface,” and the like, can refer to or can include a computer-related entity or an entity related to an operational machine with one or more specific functionalities. The entities disclosed herein can be either hardware, a combination of hardware and software, software, or software in execution. For example, a component can be, but is not limited to being, a process running on a processor, a processor, an object, an executable, a thread of execution, a program, or a computer. By way of illustration, both an application running on a server and the server can be a component. One or more components can reside within a process or thread of execution and a component can be localized on one computer or distributed between two or more computers. In another example, respective components can execute from various computer readable media having various data structures stored thereon. The components can communicate via local or remote processes such as in accordance with a signal having one or more data packets (e.g., data from one component interacting with another component in a local system, distributed system, or across a network such as the Internet with other systems via the signal). As another example, a component can be an apparatus with specific functionality provided by mechanical parts operated by electric or electronic circuitry, which is operated by a software or firmware application executed by a processor. In such a case, the processor can be internal or external to the apparatus and can execute at least a part of the software or firmware application.

As yet another example, a component can be an apparatus that provides specific functionality through electronic components without mechanical parts, wherein the electronic components can include a processor or other means to execute software or firmware that confers at least in part the functionality of the electronic components. In an aspect, a component can emulate an electronic component via a virtual machine, e.g., within a cloud computing system.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. As used herein, the term “and/or” is intended to have the same meaning as “or.” Moreover, articles “a” and “an” as used in the subject specification and annexed drawings should generally be construed to mean “one or more” unless specified otherwise or clear from context to be directed to a singular form. As used herein, the terms “example” or “exemplary” are utilized to mean serving as an example, instance, or illustration. For the avoidance of doubt, the subject matter disclosed herein is not limited by such examples. In addition, any aspect or design described herein as an “example” or “exemplary” is not necessarily to be construed as preferred or advantageous over other aspects or designs, nor is it meant to preclude equivalent exemplary structures and techniques known to those of ordinary skill in the art.

The herein disclosure describes non-limiting examples. For ease of description or explanation, various portions of the herein disclosure utilize the term “each,” “every,” or “all” when discussing various examples. Such usages of the term “each,” “every,” or “all” are non-limiting. In other words, when the herein disclosure provides a description that is applied to “each,” “every,” or “all” of some particular object or component, it should be understood that this is a non-limiting example, and it should be further understood that, in various other examples, it can be the case that such description applies to fewer than “each,” “every,” or “all” of that particular object or component.

As it is employed in the subject specification, the term “processor” can refer to substantially any computing processing unit or device comprising, but not limited to, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, or any combination thereof designed to perform the functions described herein. Further, processors can exploit nano-scale architectures such as, but not limited to, molecular and quantum-dot based transistors, switches and gates, in order to optimize space usage or enhance performance of user equipment. A processor can also be implemented as a combination of computing processing units. In this disclosure, terms such as “store,” “storage,” “data store,” data storage,” “database,” and substantially any other information storage component relevant to operation and functionality of a component are utilized to refer to “memory components,” entities embodied in a “memory,” or components comprising a memory. It is to be appreciated that memory or memory components described herein can be either volatile memory or nonvolatile memory, or can include both volatile and nonvolatile memory. By way of illustration, and not limitation, nonvolatile memory can include read only memory (ROM), programmable ROM (PROM), electrically programmable ROM (EPROM), electrically erasable ROM (EEPROM), flash memory, or nonvolatile random access memory (RAM) (e.g., ferroelectric RAM (FeRAM). Volatile memory can include RAM, which can act as external cache memory, for example. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), direct Rambus RAM (DRRAM), direct Rambus dynamic RAM (DRDRAM), and Rambus dynamic RAM (RDRAM). Additionally, the disclosed memory components of systems or computer-implemented methods herein are intended to include, without being limited to including, these and any other suitable types of memory.

What has been described above include mere examples of systems and computer-implemented methods. It is, of course, not possible to describe every conceivable combination of components or computer-implemented methods for purposes of describing this disclosure, but many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The descriptions of the various embodiments have been presented for purposes of illustration, but are not intended to be exhaustive or limited to the embodiments disclosed. Many modifications and variations will be apparent without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Various non-limiting aspects are described in the following examples.

EXAMPLE 1: A system can comprise: a processor that executes computer-executable components stored in a non-transitory computer-readable memory, wherein the computer-executable components comprise: an access component that can access an image captured by a charged-particle microscope, wherein the image depicts a specimen; and a localization component that can localize one or more outlying instantiations of a structure of interest of the specimen, based on feeding both the image and a text prompt to a large language model.

EXAMPLE 2: The system of any preceding example can be implemented, wherein the text prompt can comprise one or more sentences or sentence fragments that semantically define or describe the one or more outlying instantiations.

EXAMPLE 3: The system of any preceding example can be implemented, wherein the one or more sentences or sentence fragments can semantically define or describe the one or more outlying instantiations in terms of their sizes with respect to other instantiations of the structure of interest.

EXAMPLE 4: The system of any preceding example can be implemented, wherein the one or more sentences or sentence fragments can semantically define or describe the one or more outlying instantiations in terms of their shapes with respect to other instantiations of the structure of interest.

EXAMPLE 5: The system of any preceding example can be implemented, wherein the one or more sentences or sentence fragments can semantically define or describe the one or more outlying instantiations in terms of their distances from other instantiations of the structure of interest.

EXAMPLE 6: The system of any preceding example can be implemented, wherein the one or more sentences or sentence fragments can semantically define or describe the one or more outlying instantiations in terms of their arrangements with respect to other instantiations of the structure of interest.

EXAMPLE 7: The system of any preceding example can be implemented, wherein the one or more sentences or sentence fragments can semantically define or describe the one or more outlying instantiations in terms of their intensities with respect to other instantiations of the structure of interest.

EXAMPLE 8: The system of any preceding example can be implemented, wherein the text prompt can be user-defined and cause the charged-particle microscope to capture the image.

EXAMPLE 9: The system of any preceding example can be implemented, wherein the specimen can be a semiconductor sample or a biological sample.

In various embodiments, any combination or combinations of examples 1-9 can be implemented.

EXAMPLE 10: A computer-implemented method can comprise:
accessing, by a device operatively coupled to a processor, an image captured by a charged-particle microscope, wherein the image depicts a specimen; and localizing, by the device, one or more outlying instantiations of a structure of interest of the specimen, based on feeding both the image and a text prompt to a large language model.

EXAMPLE 11: The computer-implemented method of any preceding example can be implemented, wherein the text prompt can comprise one or more sentences or sentence fragments that semantically define or describe the one or more outlying instantiations.

EXAMPLE 12: The computer-implemented method of any preceding example can be implemented, wherein the one or more sentences or sentence fragments can semantically define or describe the one or more outlying instantiations in terms of their sizes with respect to other instantiations of the structure of interest.

EXAMPLE 13: The computer-implemented method of any preceding example can be implemented, wherein the one or more sentences or sentence fragments can semantically define or describe the one or more outlying instantiations in terms of their shapes with respect to other instantiations of the structure of interest.

EXAMPLE 14: The computer-implemented method of any preceding example can be implemented, wherein the one or more sentences or sentence fragments can semantically define or describe the one or more outlying instantiations in terms of their distances from other instantiations of the structure of interest.

EXAMPLE 15: The computer-implemented method of any preceding example can be implemented, wherein the one or more sentences or sentence fragments can semantically define or describe the one or more outlying instantiations in terms of their arrangements with respect to other instantiations of the structure of interest.

EXAMPLE 16: The computer-implemented method of any preceding example can be implemented, wherein the one or more sentences or sentence fragments can semantically define or describe the one or more outlying instantiations in terms of their intensities with respect to other instantiations of the structure of interest.

EXAMPLE 17: The computer-implemented method of any preceding example can be implemented, wherein the text prompt can be user-defined and cause the charged-particle microscope to capture the image.

EXAMPLE 18: The computer-implemented method of any preceding example can be implemented, wherein the specimen can be a semiconductor sample or a biological sample.

In various embodiments, any combination or combinations of examples 10-18 can be implemented.

EXAMPLE 19: A computer program product for facilitating text-conditioned anomaly detection for charged-particle microscopy images can comprise a non-transitory computer-readable memory having program instructions embodied therewith. In various aspects, the program instructions can be executable by a processor to cause the processor to: access a charged-particle microscope and a text prompt, wherein the charged-particle microscope can be loaded with a specimen, and wherein the text prompt can describe an outlying characteristic that might be exhibited by various instantiations of a structure of interest of the specimen; cause, in response to receipt of the text prompt, the charged-particle microscope to scan the specimen, thereby yielding a scanned image of the specimen; and generate one or more bounding boxes that circumscribe one or more instantiations of the structure of interest that exhibit the outlying characteristic, based on executing a large language model on both the scanned image and the text prompt.

EXAMPLE 20: The computer program product of any preceding example can be implemented, wherein the outlying characteristic can comprise a size, a shape, a separation distance, a layout arrangement, or a pixel intensity associated with instantiations of the structure of interest.

In various embodiments, any combination or combinations of examples 19-20 can be implemented.

In various embodiments, any combination or combinations of examples 1-20 can be implemented.

What is claimed is:

1. A system, comprising:
a processor that executes computer-executable components stored in a non-transitory computer-readable memory, wherein the computer-executable components comprise:
an access component that accesses an image captured by a charged-particle microscope, wherein the image depicts a specimen; and
a localization component that localizes one or more outlying instantiations of a structure of interest of the specimen, based on feeding both the image and a text prompt to a large language model.

2. The system of claim 1, wherein the text prompt comprises one or more sentences or sentence fragments that semantically define or describe the one or more outlying instantiations.

3. The system of claim 2, wherein the one or more sentences or sentence fragments semantically define or describe the one or more outlying instantiations in terms of their sizes with respect to other instantiations of the structure of interest.

4. The system of claim 2, wherein the one or more sentences or sentence fragments semantically define or describe the one or more outlying instantiations in terms of their shapes with respect to other instantiations of the structure of interest.

5. The system of claim 2, wherein the one or more sentences or sentence fragments semantically define or describe the one or more outlying instantiations in terms of their distances from other instantiations of the structure of interest.

6. The system of claim 2, wherein the one or more sentences or sentence fragments semantically define or describe the one or more outlying instantiations in terms of their arrangements with respect to other instantiations of the structure of interest.

7. The system of claim 2, wherein the one or more sentences or sentence fragments semantically define or describe the one or more outlying instantiations in terms of their intensities with respect to other instantiations of the structure of interest.

8. The system of claim 1, wherein the text prompt is user-defined and causes the charged-particle microscope to capture the image.

9. The system of claim 1, wherein the specimen is a semiconductor sample or a biological sample.

10. A computer-implemented method, comprising:
accessing, by a device operatively coupled to a processor, an image captured by a charged-particle microscope, wherein the image depicts a specimen; and
localizing, by the device, one or more outlying instantiations of a structure of interest of the specimen, based on feeding both the image and a text prompt to a large language model.

11. The computer-implemented method of claim 10, wherein the text prompt comprises one or more sentences or sentence fragments that semantically define or describe the one or more outlying instantiations.

12. The computer-implemented method of claim 11, wherein the one or more sentences or sentence fragments semantically define or describe the one or more outlying instantiations in terms of their sizes with respect to other instantiations of the structure of interest.

13. The computer-implemented method of claim 11, wherein the one or more sentences or sentence fragments semantically define or describe the one or more outlying instantiations in terms of their shapes with respect to other instantiations of the structure of interest.

14. The computer-implemented method of claim 11, wherein the one or more sentences or sentence fragments semantically define or describe the one or more outlying instantiations in terms of their distances from other instantiations of the structure of interest.

15. The computer-implemented method of claim 11, wherein the one or more sentences or sentence fragments semantically define or describe the one or more outlying instantiations in terms of their arrangements with respect to other instantiations of the structure of interest.

16. The computer-implemented method of claim 11, wherein the one or more sentences or sentence fragments semantically define or describe the one or more outlying instantiations in terms of their intensities with respect to other instantiations of the structure of interest.

17. The computer-implemented method of claim 10, wherein the text prompt is user-defined and causes the charged-particle microscope to capture the image.

18. The computer-implemented method of claim 10, wherein the specimen is a semiconductor sample or a biological sample.

19. A computer program product for facilitating text-conditioned anomaly detection for charged-particle microscopy images, the computer program product comprising a non-transitory computer-readable memory having program instructions embodied therewith, the program instructions executable by a processor to cause the processor to:
access a charged-particle microscope and a text prompt, wherein the charged-particle microscope is loaded with a specimen, and wherein the text prompt describes an outlying characteristic that might be exhibited by various instantiations of a structure of interest of the specimen;
cause, in response to receipt of the text prompt, the charged-particle microscope to scan the specimen, thereby yielding a scanned image of the specimen; and
generate one or more bounding boxes that circumscribe one or more instantiations of the structure of interest that exhibit the outlying characteristic, based on executing a large language model on both the scanned image and the text prompt.

20. The computer program product of claim 19, wherein the outlying characteristic comprises a size, a shape, a separation distance, a layout arrangement, or a pixel intensity associated with instantiations of the structure of interest.
